(19) United States
(12) Patent Application Publication
(10) Pub. No.: US 2026/0033103 A1
(43) Pub. Date: Jan. 29, 2026

(54) Display Apparatus

(71) Applicant: LG Display Co., Ltd., Seoul (KR)

(72) Inventors: Inhwan Gu, Seoul (KR); Jaebin Song, Seoul (KR)

(21) Appl. No.: 19/233,231

(22) Filed: Jun. 10, 2025

(30) Foreign Application Priority Data
Jul. 23, 2024 (KR) 10-2024-0097541

(51) Int. Cl. H10H 29/855

(52) U.S. Cl. CPC H10H 29/855

(57) ABSTRACT

A display apparatus may include a substrate, a plurality of pixel driving circuits disposed on the substrate, a plurality of light-emitting elements disposed on the pixel driving circuits and electrically connected to the pixel driving circuits, respectively, at least one optical layer covering the plurality of light-emitting elements, and a cover layer disposed on the optical layer, wherein a refractive index of the cover layer may be smaller than or equal to a refractive index of one of the at least one optical layer.

### CROSS REFERENCE TO RELATED APPLICATION

This application claims priority from Republic of Korea Patent Application No. 10-2024-0097541 filed on Jul. 23, 2024, which is hereby incorporated by reference in its entirety.

### BACKGROUND

### Field of Technology

The present disclosure relates to a display apparatus.

### Description of the Related Art

Display apparatuses are applied to various electronic devices such as televisions (TVs), mobile phones, notebooks, tablets, etc.

Examples of a display apparatus include an organic light-emitting diode (OLED) display apparatus that emits light by itself, a liquid crystal display (LCD) apparatus that requires a separate light source, etc.

Recently, display apparatuses including a light-emitting diode (LED) have been attracting attention as next-generation display apparatuses. Since a light-emitting element is formed of an inorganic material rather than an organic material, the display apparatus including the LED has a faster lighting speed, better luminous efficiency, and higher luminance images than an LCD or OLED apparatus.

### SUMMARY

Generally, a multilayered structure including a polarizing layer on a light-emitting element may be disposed in a display apparatus. The polarizing layer can improve outdoor visibility. Light emitted from a light source in the display apparatus may be emitted to the outside through the multilayered structure.

Some of light incident on the multilayered structure may be extinguished without being emitted to the outside due to total internal reflection. As the amount of light internally totally reflected in the multilayered structure increases, the amount of light extinguished increases, thereby reducing light extraction efficiency.

When the light extraction efficiency is reduced, power consumption can increase to drive the display apparatus while maintaining the quality of the display apparatus.

Accordingly, inventors of the present disclosure have invented a display apparatus capable of increasing light extraction efficiency through various tests.

Embodiments of the present disclosure are directed to providing a display apparatus in which it is possible to increase light extraction efficiency.

In addition, embodiments of the present disclosure are directed to providing a display apparatus in which it is possible to increase the amount of light using recycling internally totally reflected light.

Objects of the present disclosure are not limited to the above-described objects, and other objects that are not mentioned will be able to be clearly understood by those skilled in the art based on the following description.

A display apparatus according to embodiments of the present disclosure may include a substrate, a plurality of pixel driving circuits disposed on the substrate, a plurality of light-emitting elements disposed on the pixel driving circuits and electrically connected to the pixel driving circuits, respectively, at least one optical layer covering the plurality of light-emitting elements, and a cover layer disposed on the optical layer, wherein a refractive index of the cover layer is smaller than or equal to a refractive index of one of the at least one optical layer.

### BRIEF DESCRIPTION OF THE DRAWINGS

FIG. 1 is an exploded perspective view of a display apparatus according to an embodiment of the present disclosure.

FIG. 2 is a plan view of the display apparatus according to an embodiment of the present disclosure.

FIG. 3 is an enlarged view of the display apparatus according to an embodiment of the present disclosure.

FIG. 4 is a view illustrating a circuit structure according to an embodiment of the present disclosure.

FIG. 5 is a plan view of the display apparatus according to an embodiment of the present disclosure.

FIG. 6 is a plan view of the display apparatus according to an embodiment of the present disclosure.

FIG. 7 is a plan view of the display apparatus according to an embodiment of the present disclosure.

FIG. 8 is a cross-sectional view of the display apparatus according to one embodiment of the present disclosure.

FIG. 9 is a cross-sectional view of the display apparatus according to one embodiment of the present disclosure.

FIGS. 10 to 13 are views illustrating a device to which the display apparatus according to embodiments of the present disclosure is applied.

FIG. 14 is a plan view illustrating an area in which one of a plurality of pixel driving circuits is disposed according to one embodiment of the present disclosure.

FIG. 15 is a cross-sectional view illustrating area “II” in FIG. 8 according to one embodiment of the present disclosure.

FIG. 16 is a view illustrating a third optical layer according to one embodiment of the present disclosure.

FIG. 17 is a cross-sectional view along line II-III′ in FIG. 2 according to another embodiment of the present disclosure.

FIG. 18 is a cross-sectional view illustrating area “IV” in FIG. 17 according to one embodiment of the present disclosure.

FIG. 19 is a view illustrating a third optical layer according to another embodiment of the present disclosure.

### DETAILED DESCRIPTION

Advantages and features of the present disclosure and methods for achieving them will become clear by referencing embodiments described below in detail in conjunction with the accompanying drawings. However, the present disclosure is not limited to the embodiments disclosed below but will be implemented in various different forms, and these embodiments are merely provided to make the disclosure of the present disclosure complete and fully inform those skilled in the art to which the present disclosure pertains of the scope of the present disclosure.

Since shapes, sizes, ratios, angles, numbers, etc. disclosed in the drawings for describing the embodiments of the present disclosure are illustrative, the present disclosure is not limited to the illustrated items. The same reference number denotes the same components throughout the disclosure. In addition, in describing the present disclosure, when it is determined that the detailed description of a related known technology may unnecessarily obscure the gist of the present disclosure, the detailed description thereof will be omitted. When “comprises,” “has,” “includes,” and the like described in the present disclosure are used, other parts may be added unless “only” is used. When a component is expressed in a singular form, it includes a case in which the component is provided as a plurality of components unless specifically stated otherwise.

In construing a component, the component is construed as including a margin of error even when there is no separate explicit description.

When a positional relationship is described, for example, when the positional relationship between two parts is described using “on,” “above,” “under,” “next to,” etc., one or more other parts may be positioned between the two parts unless “immediately” or “directly” is used.

When a temporal relationship is described, for example, when the temporal relationship is described using “after,” “subsequently,” “then,” “before,” etc., it may include a non-consecutive case unless the term “immediately” or “directly” is used.

Although terms such as first and second are used to describe various components, these components are not limited by these terms. The terms are only used to distinguish one component from another. Accordingly, a first component described below may be a second component within the technical spirit of the present disclosure.

In the description of the components of the present disclosure, terms such as first, second, A, B, (a), and (b) may be used. These terms are only for the purpose of distinguishing one component from another component, and the nature, sequence, order, or the like of the corresponding component is not limited by these terms.

When a certain component is described as being “connected,” “coupled,” “joined,” or “attached” to another component, the certain component may be connected, coupled, joined, or attached directly to another component, but it should be understood that still another component may be interposed between the components that may be connected, coupled, joined, or attached indirectly unless stated specifically otherwise.

When a component or a layer is described as “coming into contact with” or “overlapping” another component or layer, the component or the layer may come into direct contact with or directly overlap another component or layer, but it should be understood that still another component may be interposed between the components that may come into indirect contact with and indirectly overlap each other unless stated specifically otherwise.

It should be understood that “at least one” includes any combination of one or more of associated components. For example, “at least one of first, second, and third components” may include not only the first, second, or third component, but also any combination of two or more of the first, second, and third components.

The terms “first direction,” “second direction,” “third direction,” “X-axis direction,” “Y-axis direction,” and “Z-axis direction” should not be construed as merely the geometric relationship in which the relationship therebetween is perpendicular and may refer to a wider directionality within the range in which the configuration of the present disclosure may act functionally.

Features of various embodiments of the present disclosure may be coupled or combined partially or entirely, various technological interworking and driving are made possible, and the embodiments may be implemented independently of each other or implemented together in an associated relationship.

Hereinafter, example embodiment of the present disclosure will be described in detail with reference to the accompanying drawings.

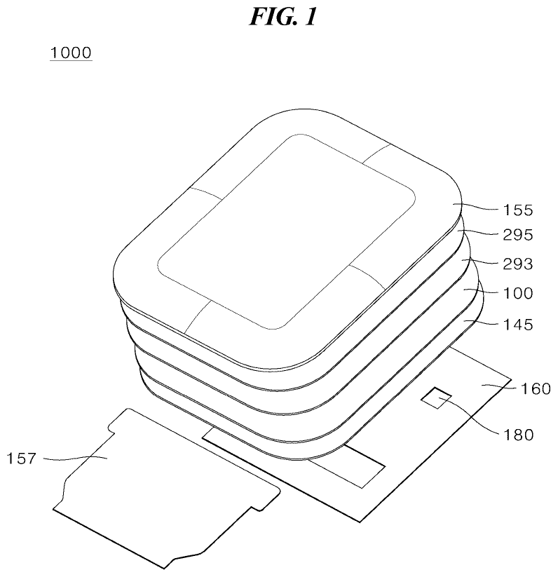

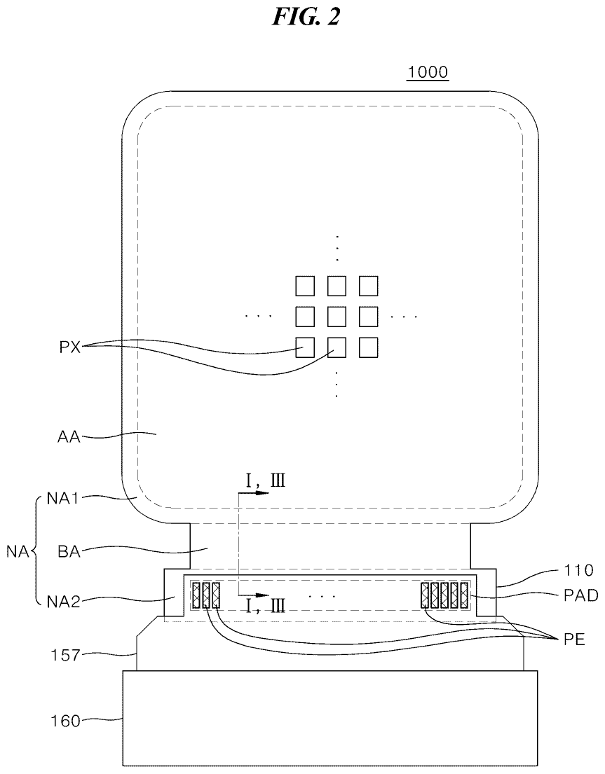

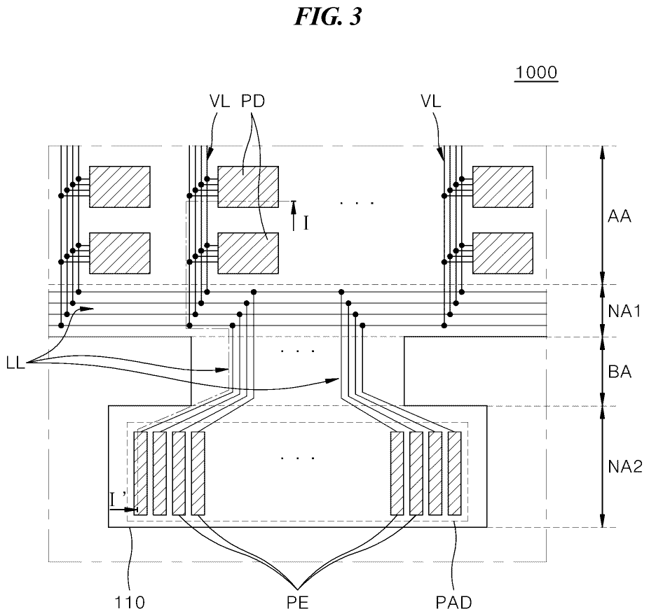

FIG. 1 is an exploded perspective view of a display apparatus according to an embodiment of the present disclosure. FIG. 2 is a plan view of the display apparatus according to an embodiment of the present disclosure. FIG. 3 is an enlarged view of the display apparatus according to an embodiment of the present disclosure.

Referring to FIGS. 1 to 3, a display apparatus 1000 according to the embodiment of the present disclosure may include a display panel 100, a polarizing layer 293, an adhesive layer 295, a cover member 155, a support substrate 145, a flexible circuit board 157, and a printed circuit board 160.

For example, the display apparatus 1000 may include a substrate 110. The substrate 110 may be a member for supporting other components of the display apparatus 1000. The substrate 110 may be formed of an insulation material. For example, the substrate 110 may be formed of glass, a resin, etc. In addition, the substrate 110 may be formed of a flexible material. For example, the substrate 110 may be made of a flexible plastic material, such as polyimide (PI). However, the embodiments of the present disclosure are not limited thereto.

The display panel 100 may implement information, video, and/or image provided to a user. For example, the display panel 100 may include a display area AA and a non-display area NA. For example, the substrate 110 may include the display area AA and the non-display area NA. Descriptions of the display area AA and the non-display area NA are not limited to the substrate 110, but descriptions thereof may be made with respect to the display apparatus 1000.

The display area AA may be an area on which an image is displayed. The display area AA may include a plurality of pixels PX. Each of the plurality of pixels PX may be formed of a plurality of sub-pixels. A plurality of light-emitting elements may be disposed in each of the plurality of sub-pixels. A plurality of light-emitting elements may be configured differently according to the type of the display apparatus 1000. For example, when the display apparatus 1000 is an inorganic light-emitting display apparatus, the light-emitting element may be a light-emitting diode (LED), a micro LED, or a mini LED, but the embodiments of the present disclosure are not limited thereto.

The non-display area NA may be an area on which no image is displayed. Various lines, circuits, and the like for driving the plurality of pixels PX of the display area AA may be disposed on the non-display area NA. For example, in the non-display area NA, various lines and driving circuits may be mounted, and a pad part PAD to which an integrated circuit, a printed circuit, and the like are connected may be disposed, but the embodiments of the present disclosure are not limited thereto.

For example, the driving circuit may be a data driving circuit and/or a gate driving circuit, but the embodiments of the present disclosure are not limited thereto. Lines for supplying control signals for controlling driving circuits may be disposed. For example, the control signals may include various types of timing signals including a clock signal, an input data enable signal, and synchronization signals, but the embodiments of the present disclosure are not limited thereto. The control signals may be received through the pad part PAD. For example, link lines LL for transmitting signals may be disposed in the non-display area NA. For example, driving components, such as a flexible circuit board 157 and a printed circuit board 160, may be connected to the pad part PAD.

According to the present disclosure, the non-display area NA may include a first non-display area NA1, a bending area BA, and a second non-display area NA2. For example, the first non-display area NA1 may be an area that surrounds at least a part of the display area AA. The bending area BA may be an area extending from at least one of a plurality of sides of the first non-display area NA1 and may be a bendable area. The second non-display area NA2 may be an area extending from the bending area BA and may have the pad part PAD disposed therein. For example, the bending area BA may be bent, and the remaining area of the substrate 110 not including the bending area BA may be flat. In this case, as the bending area BA is bent, the second non-display area NA2 may be located on a rear surface of the display area AA. However, the embodiments of the present disclosure are not limited thereto.

The display area AA of the substrate 110 or the display apparatus 1000 may be configured in various shapes according to the design of the display apparatus 1000. For example, the display area AA may be formed in a rectangular shape with four rounded corners, but the embodiments of the present disclosure are not limited thereto. As another example, the display area AA may be formed in a rectangular shape with four right-angled corners, a circular shape, etc., but the embodiments of the present disclosure are not limited thereto.

According to the present disclosure, a width of the second non-display area NA2 in which a plurality of pad electrodes PE are disposed may be greater than a width of the bending area BA in which only the plurality of link lines LL are disposed. In addition, a width of the display area AA in which the plurality of sub-pixels are disposed may be greater than the width of the bending area BA in which only the plurality of link lines LL are disposed. In the drawings, the width of the bending area BA is illustrated as being narrower than widths of other areas of the substrate 110, but the shape of the substrate 110 including the bending area BA is illustrative, and the embodiments of the present disclosure are not limited thereto.

Referring to FIG. 3, a plurality of pixel driving circuits PD may be disposed in the display area AA. The plurality of pixel driving circuits PD may be circuits for driving the light-emitting elements of the plurality of sub-pixels. Each of the plurality of pixel driving circuits PD may include a plurality of transistors including a driving transistor, a storage capacitor, etc., and supply control signals, power, and a driving current to the light-emitting elements of the plurality of sub-pixels in order to control the light-emitting operation of the plurality of light-emitting elements. For example, the pixel driving circuit PD may include a power line and a signal line for controlling light-emitting on/off and/or light-emitting time of the light-emitting element. For example, the plurality of pixel driving circuits PD may be drivers manufactured using a process of manufacturing a metal-oxide-semiconductor field effect transistor (MOSFET) on a semiconductor substrate, but the embodiments of the present disclosure are not limited thereto. The driver may include the plurality of pixel driving circuits PD and drive the plurality of sub-pixels. For example, the plurality of pixel driving circuits PD may include micro drivers μDriver, but the embodiments of the present disclosure are not limited thereto. For example, the plurality of pixel driving circuits PD may include driver chips, but the embodiments of the present disclosure are not limited thereto.

Referring to FIG. 1 again, the flexible circuit board 157 and the printed circuit board 160 may be disposed below the display panel 100. The flexible circuit board 157 and the printed circuit board 160 may be disposed at at least one edge of the display panel 100, but the embodiments of the present disclosure are not limited thereto. One side of the flexible circuit board 157 may be attached to the display panel 100, and the other side may be attached to the printed circuit board 160, but the embodiments of the present disclosure are not limited thereto. The flexible circuit board 157 may be a flexible film, but the embodiments of the present disclosure are not limited thereto.

The pad part PAD including the plurality of pad electrodes PE may be disposed in the second non-display area NA2. A driving component including one or more flexible circuit boards (or flexible films) 157 and the printed circuit board 160 may be attached or bonded to the pad part PAD. The plurality of pad electrodes PE of the pad part PAD may be electrically connected to one or more flexible circuit boards (or flexible films) 157, and various signals (or power) from the printed circuit board 160 and the flexible circuit board (or the flexible film) 157 may be transmitted to the plurality of pixel driving circuits PDs of the display area AA.

The flexible circuit board (or the flexible film) 157 may be a film in which various types of components are disposed on a flexible base film. For example, a drive integrated circuit (IC), such as a gate driver IC or a data driver IC, may be disposed on the flexible circuit board (or the flexible film) 157, but the embodiments of the present disclosure are not limited thereto. The drive IC may be a component for processing data and driving signals for displaying an image. The drive IC may be disposed by a method of a chip on glass (COG), a chip on film (COF), a tape carrier package (TCP), etc. according to a mounting method, but the embodiments of the present disclosure are not limited thereto. The flexible circuit board (or the flexible film) 157 may be attached or bonded to the plurality of pad electrodes PE through a conductive adhesive layer, but the embodiments of the present disclosure are not limited thereto.

The printed circuit board 160 may be a component that is electrically connected to one or more flexible circuit boards (or flexible films) 157 and supplies signals to the drive IC. The printed circuit board 160 may be disposed at one side of the flexible circuit board (or the flexible film) 157 and electrically connected to the flexible circuit board (or the flexible film) 157. Various types of components for supplying various signals to the drive IC may be disposed on the printed circuit board 160. For example, various components, such as a timing controller, a power supply, a memory, a processor, etc. may be disposed on the printed circuit board 160. For example, the printed circuit board 160 may include a power management integrated circuit (PMIC), but the embodiments of the present disclosure are not limited thereto.

The printed circuit board 160 may include at least one hole 180, but the embodiments of the present disclosure are not limited thereto. An internal component for detecting ambient light, temperature, and the like that may be provided to a plurality of sensors may be disposed in an area corresponding to the at least one hole 180. For example, the internal component may include an ambient light sensor (ALS), a temperature sensor, etc., but the embodiments of the present disclosure are not limited thereto. For example, the hole 180 may be a transmissive hole or the like, but the embodiments of the present disclosure are not limited thereto.

Referring to FIG. 1, the polarizing layer 293 may be disposed on the display panel 100. The polarizing layer 293 can prevent or reduce light generated from an external light source from entering the display panel 100 and affecting the light-emitting element and the like.

The cover member 155 may be disposed on the polarizing layer 293. The cover member 155 may be a member for protecting the display panel 100. The adhesive layer 295 may be disposed between the polarizing layer 293 and the cover member 155. The cover member 155 may be attached to the display panel 100 by the adhesive layer 295. The adhesive layer 295 may include an optically clear adhesive (OCA), an optically clear resin (OCR), a pressure sensitive adhesive (PSA), etc., but the embodiments of the present disclosure are not limited thereto.

The support substrate 145 may be disposed between the display panel 100 and the printed circuit board 160. The support substrate 145 may reinforce the rigidity of the display panel 100. The support substrate 145 may be a backplate, but the embodiments of the present disclosure are not limited thereto.

Referring to FIGS. 1 to 3, the plurality of link lines LL may be disposed in the non-display area NA. The plurality of link lines LL may be lines that transmit various types of signals from the one or more flexible circuit boards (or flexible films) 157 and the printed circuit board 160 to the display area AA. The plurality of link lines LLs may extend from the plurality of pad electrodes PE of the second non-display area NA2 toward the bending area BA and the first non-display area NA1 and may be electrically connected to a plurality of driving lines VLs of the display area AA. The plurality of pixel driving circuits PD may be driven by receiving signals from the one or more flexible circuit boards (or flexible films) 157 and the printed circuit board 160 through the driving lines VL of the display area AA and the link lines LL of the non-display area NA.

For example, the plurality of driving lines VL along with the plurality of link lines LL may be lines for transmitting the signals output from the flexible circuit boards (or the flexible films) 157 and the printed circuit board 160 to the plurality of pixel driving circuits PD. The plurality of driving lines VL may be disposed in the display area AA and electrically connected to the plurality of pixel driving circuits PD, respectively. The plurality of driving lines VL may extend from the display area AA toward the non-display area NA and may be electrically connected to the plurality of link lines LL. Accordingly, the signals output from the flexible circuit boards (or the flexible films) 157 and the printed circuit board 160 may be transmitted to the plurality of pixel driving circuits PD through the plurality of link lines LL and the plurality of driving lines VL, respectively.

As the bending area BA is bent, parts of the plurality of link lines LL may also be bent. Since stress is concentrated on the bent parts of the bent link lines LL, cracks may occur in the link lines LL. Accordingly, the plurality of link lines LL may be formed of an excellent flexible conductive material to reduce cracks when the bending area BA is bent. For example, the plurality of link lines LL may be formed of an excellent flexible conductive material, such as gold (Au), silver (Ag), aluminum (Al), etc., but the embodiments of the present disclosure are not limited thereto. In addition, the plurality of link lines LL may be formed of one of various conductive materials used in the display area AA. For example, the plurality of link lines LL may be formed of molybdenum (Mo), chromium (Cr), titanium (Ti), nickel (Ni), neodymium (Nd), copper (Cu), and an alloy of silver (Ag) and magnesium (Mg), or an alloy thereof, but the embodiments of the present disclosure are not limited thereto. The plurality of link lines LL may be formed of a multilayered structure including various conductive materials. For example, the plurality of link lines LL may be formed of a triple layer structure of titanium (Ti)/aluminum (Al)/titanium (Ti), but the embodiments of the present disclosure are not limited thereto.

The plurality of link lines LLs may be formed in various shapes to reduce stress. At least some of the plurality of link lines LL disposed on the bending area BA may extend in the same direction as an extension direction of the bending area BA or extend in a different direction from the extension direction of the bending area BA to reduce stress. For example, when the bending area BA extends in one direction from the first non-display area NA1 to the second non-display area NA2, at least some of the link lines LL disposed on the bending area BA may extend in a direction oblique to the one direction. For another example, the at least some of the plurality of link lines LL may be formed as patterns of various shapes. For example, the at least some of the plurality of link lines LL disposed on the bending area BA may have a shape in which a conductive pattern having at least one of a diamond shape, a rhombus shape, a trapezoidal wave shape, a triangular wave shape, a sawtooth wave shape, a sine wave shape, a circular shape, and an omega (Ω) shape is repeatedly disposed, but the embodiments of the present disclosure are not limited thereto. Accordingly, to minimize the stress concentrated on the plurality of link lines LL and cracks caused by the stress, the shapes of the plurality of link lines LL may be formed in various shapes including the above shapes, but the embodiments of the present disclosure are not limited thereto.

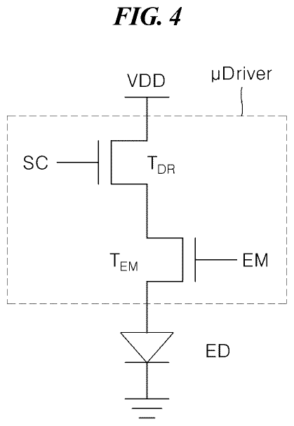

FIG. 4 is a view illustrating a circuit structure according to an embodiment of the present disclosure. FIG. 4 illustrates an example in which one light-emitting element ED is connected to the micro driver μDriver, but the embodiments of the present disclosure are not limited thereto. For example, eight light-emitting elements (LEDs) may be connected to one micro driver μDriver. As another example, 16 light-emitting elements ED may be connected to one micro driver μDriver, or 32 light-emitting elements ED or 64 light-emitting elements ED may be connected to one micro driver μDriver simultaneously. The light-emitting element ED may be a micro light emitting element (μLED).

One micro driver μDriver may include a driving transistor TDR and a light-emitting transistor TEM, but the embodiments of the present disclosure are not limited thereto.

For example, the driving transistor TDR may have a first electrode to which a high-potential power voltage VDD applied, a second electrode to which a first electrode of the light-emitting transistor TEM is connected, and a gate electrode to which a scan signal SC is applied. The scan signal SC applied to the gate electrode of the driving transistor TDR is DC power, and a fixed reference voltage (Vref) may be applied for each frame, but the embodiments of the present disclosure are not limited thereto.

The light-emitting transistor TEM may have a first electrode to which the second electrode of the driving transistor TDR is connected, a second electrode to which the light-emitting element ED is connected, and a gate electrode to which a light-emitting signal EM is applied. The light-emitting signal EM applied to the gate electrode of the light-emitting transistor TEM may be a pulse width modulation (PWM) signal that varies for each frame, but the embodiments of the present disclosure are not limited thereto.

The light-emitting element ED may have a first electrode connected to the second electrode of the light-emitting transistor TEM and the second electrode connected to the ground. For example, the first electrode may be an anode electrode, and the second electrode may be a cathode electrode, but the embodiments of the present disclosure are not limited thereto.

The driving transistor TDR and the light-emitting transistor TEM may each be an n-type transistor or a p-type transistor.

The micro driver μDriver may turn on the driving transistor TDR by the scan signal SC applied from a timing controller (T-CON) and turn on the light-emitting transistor TEM by the light-emitting signal EM. Accordingly, a driving current may be applied to the light-emitting element ED via the driving transistor TDR and the light-emitting transistor TEM by the high-potential power voltage VDD applied to the first electrode of the driving transistor TDR so that the light-emitting element ED may emit light.

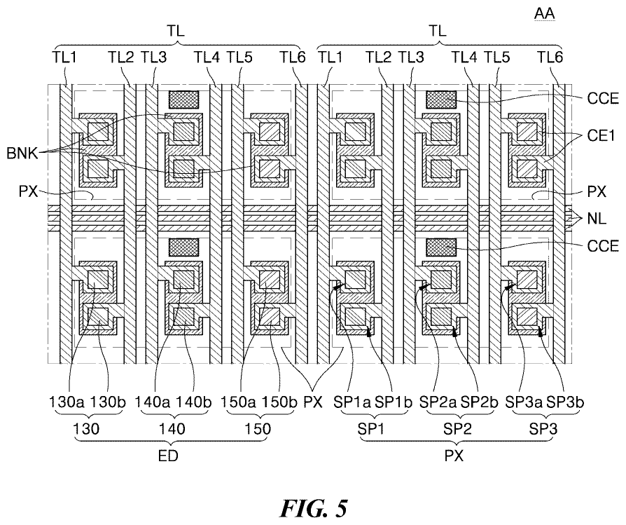

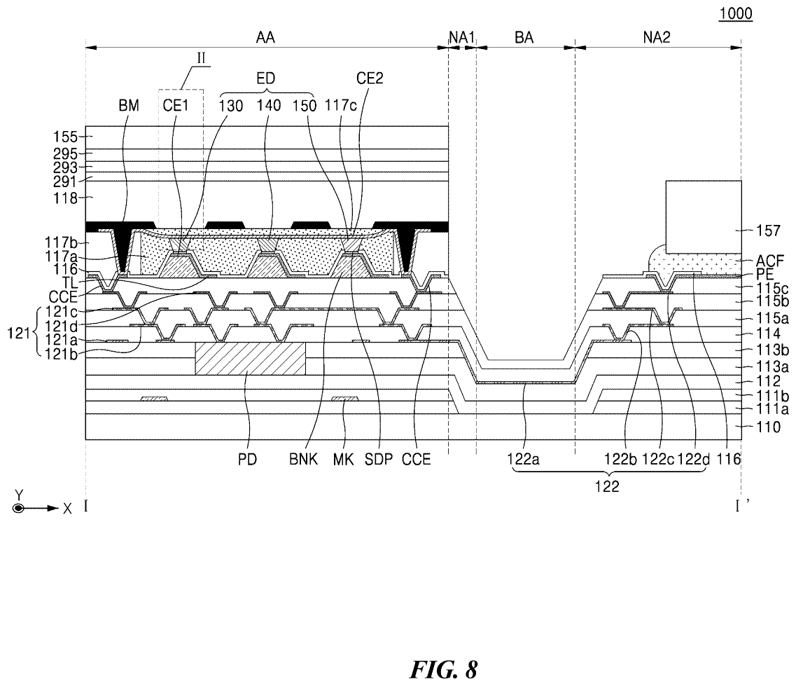

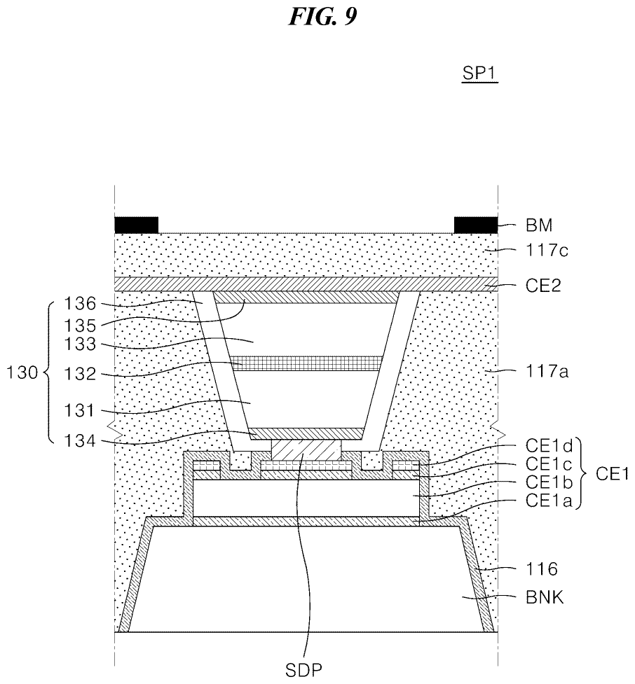

FIGS. 5 to 7 are plan views of the display apparatus according to an embodiment of the present disclosure. FIGS. 8 and 9 are cross-sectional views of the display apparatus according to one embodiment of the present disclosure.

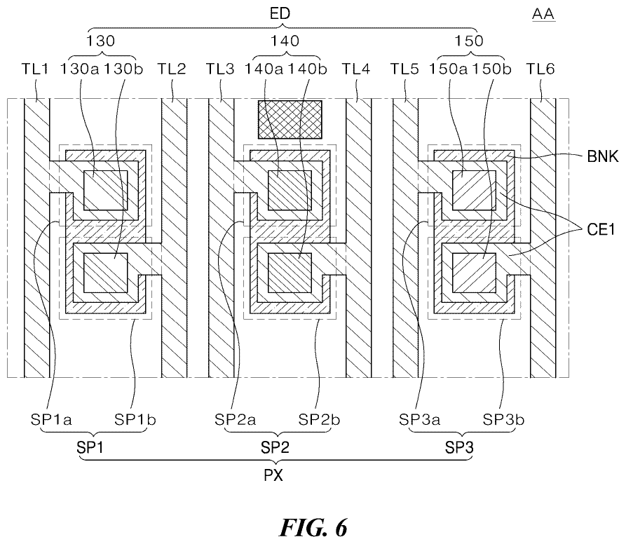

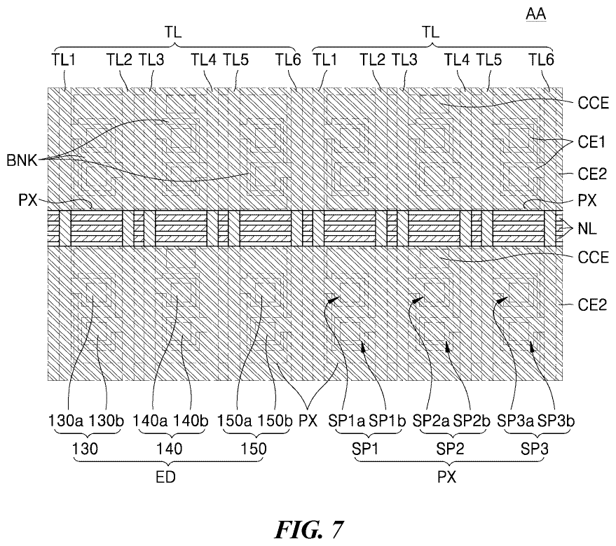

For example, FIG. 5 is an enlarged plan view of a display area including a plurality of pixels. For example, FIG. 6 is an enlarged plan view of a display area including one pixel. For example, FIG. 7 is an enlarged plan view of a display area including a plurality of pixels. For example, FIG. 8 is a cross-sectional view of the display area AA, the first non-display area NA1, the bending area BA, and the second non-display area NA2. For example, FIG. 9 is a cross-sectional view of a display area including one sub-pixel SP1. FIG. 8 is a cross-sectional view of the display apparatus along line I-I′ in FIG. 3. For convenience of illustration, FIG. 3 illustrates line I-I′ that does not overlap the driving line VL and the link line LL, but line I-I′ of FIG. 3 is intended to indicate the same location as an adjacent driving line VL and link line LL.

FIGS. 5 and 6 illustrate a plurality of signal lines TL, a plurality of communication lines NL, a plurality of first electrodes CE1, a plurality of banks BNK, and a plurality of light-emitting elements ED, but the embodiments of the present disclosure are not limited thereto. FIG. 7 is an enlarged plan view of FIG. 5 in which a plurality of second electrodes CE2 are additionally disposed.

Referring to FIGS. 5, 6, and 9, the plurality of pixels PX formed of a plurality of sub-pixels may be disposed in the display area AA. Each of the plurality of sub-pixels may include the light-emitting element ED and independently emit light. The plurality of sub-pixels may be disposed in a matrix form that is formed of a plurality of rows and a plurality of columns, but the embodiments of the present disclosure are not limited thereto.

The plurality of sub-pixels may include a first sub-pixel SP1, a second sub-pixel SP2, and a third sub-pixel SP3. For example, one of the first sub-pixel SP1, the second sub-pixel SP2, and the third sub-pixel SP3 may be a red sub-pixel, another may be a green sub-pixel, and the remaining one may be a blue sub-pixel. The types of the plurality of sub-pixels are illustrative, and the embodiments of the present disclosure are not limited thereto.

Each of the plurality of pixels PX may include one or more first sub-pixels SP1, one or more second sub-pixels SP2, and one or more third sub-pixels SP3. For example, one pixel PX may include one pair of first sub-pixels SP1, one pair of second sub-pixels SP2, and one pair of third sub-pixels SP3. The pair of first sub-pixels SP1 may be formed of a 1-1 sub-pixel SP1a and a 1-2 sub-pixel SP1b. The pair of second sub-pixels SP2 may be formed of a 2-1 sub-pixel SP2a and a 2-2 sub-pixel SP2b. The pair of third sub-pixels SP3s may be formed of a 3-1 sub-pixel SP3a and a 3-3 sub-pixel SP3b. For example, one pixel PX may include the 1-1 sub-pixel SP1a and the 1-2 sub-pixel SP1b, the 2-1 sub-pixel SP2a and the 2-2 sub-pixel SP2b, and the 3-1 sub-pixel SP3a and the 3-2 sub-pixel SP3b, but the embodiments of the present disclosure are not limited thereto.

The plurality of sub-pixels forming one pixel PX may be arranged in various ways. For example, in one pixel PX, a pair of first sub-pixels SP1 may be disposed in the same column, a pair of second sub-pixels SP2 may be disposed in the same column, and a pair of third sub-pixels SP3 may be disposed in the same column. The first sub-pixel SP1, the second sub-pixel SP2, and the third sub-pixel SP3 may be disposed in the same row. The number and arrangement of plurality of sub-pixels forming one pixel PX are illustrative, and the embodiments of the present disclosure are not limited thereto.

The plurality of signal lines TL may be disposed in an area between the plurality of sub-pixels. The plurality of signal lines TL may extend in a column direction between the plurality of sub-pixels. The plurality of signal lines TL may be lines that transmit an anode voltage output from the pixel driving circuit PD to the plurality of sub-pixels. For example, the plurality of signal lines TL may be electrically connected to the plurality of pixel driving circuits PD and the first electrodes CE1 of the plurality of sub-pixels. The anode voltage output from the pixel driving circuit PD may be transmitted to the first electrodes CE1 of the plurality of sub-pixels through the plurality of signal lines TL. For example, the first electrode CE1 may be an electrode that is electrically connected to an anode electrode 134 of the light-emitting element ED. Accordingly, the anode voltage from the signal line TL may be transmitted to the anode electrode 134 of the light-emitting element ED through the first electrode CE1.

Accordingly, the structure of the display apparatus 1000 can be simplified using the pixel driving circuit PD in which a plurality of pixel circuits are integrated instead of forming a plurality of transistors and storage capacitors in each of the plurality of sub-pixels. In addition, since circuits disposed in each of the plurality of sub-pixels are integrated in one pixel driving circuit PD, high-efficiency, low-power driving can be made possible.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to the pair of first sub-pixels SP1, respectively. The third signal line TL3 and the fourth signal line TL4 may be electrically connected to the pair of second sub-pixels SP2, respectively. The fifth signal line TL5 and the sixth signal line TL6 may be electrically connected to the pair of third sub-pixels SP3, respectively.

The first signal line TL1 may be disposed at one side of the pair of first sub-pixels SP1, and the second signal line TL1 may be disposed at another side of the pair of first sub-pixels SP1. The first signal line TL1 may be electrically connected to the first electrode CE1 of one of the pair of first sub-pixels SP1, for example, the 1-1 sub-pixel SP1a. The second signal line TL2 may be electrically connected to the first electrode CE1 of the other of the pair of first sub-pixels SP1, for example, the 1-2 sub-pixel SP1b.

The third signal line TL3 may be disposed at one side of the pair of second sub-pixels SP2, and the fourth signal line TL4 may be disposed at another side of the pair of second sub-pixels SP2. For example, the third signal line TL3 may be disposed adjacent to the second signal line TL2. The third signal line TL3 may be electrically connected to the first electrode CE1 of one of the pair of second sub-pixels SP2, for example, the 2-1 sub-pixel SP2a. The fourth signal line TL4 may be electrically connected to the first electrode CE1 of the other of the pair of second sub-pixels SP2, for example, the 2-2 sub-pixel SP2b.

The fifth signal line TL5 may be disposed at one side of the pair of third sub-pixels SP3, and the sixth signal line TL6 may be disposed at another side of the pair of third sub-pixels SP3. For example, the fifth signal line TL5 may be disposed adjacent to the fourth signal line TL4. The sixth signal line TL6 may be disposed adjacent to the first signal line TL1 connected to a neighboring pixel PX. The fifth signal line TL5 may be electrically connected to the first electrode CE1 of one of the pair of third sub-pixels SP3, for example, the 3-1 sub-pixel SP3a. The sixth signal line TL6 may be electrically connected to the first electrode CE1 of the other of the pair of third sub-pixels SP3, for example, the 3-2 sub-pixel SP3b.

The plurality of signal lines TL may be formed of a conductive material. For example, the plurality of signal lines TL may be formed of a conductive material, such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but the embodiments of the present disclosure are not limited thereto. As another example, the plurality of signal line TL may be formed in a multilayered structure of the conductive material. For example, the plurality of signal lines TL may be formed in a multilayered structure of titanium (Ti)/aluminum (Al)/indium tin oxide (ITO), but the embodiments of the present disclosure are not limited thereto.

The plurality of communication lines NL may be disposed in an area between the plurality of pixels PX. The plurality of communication lines NL may be disposed to extend in a row direction in the area between the plurality of pixels PX. The plurality of communication lines NL may be disposed in an area between a plurality of second electrodes CE2 and may not overlap the plurality of second electrodes CE2. For example, the plurality of communication lines NL may be lines used for short-range communication, such as near field communication (NFC). The plurality of communication lines NL may serve as antennas. For example, the plurality of communication lines NL may be a plurality of connection lines or the like, but the embodiments of the present disclosure are not limited thereto.

According to the present disclosure, the bank BNK may be disposed in each of the plurality of sub-pixels. The plurality of banks BNK may be structures on which the plurality of light-emitting elements ED are seated. The plurality of banks BNK may give guidance related to the locations of the plurality of light-emitting elements ED in a transfer process of transferring the plurality of light-emitting elements ED onto the display apparatus 1000. In the transfer process of the plurality of light-emitting elements ED, the plurality of light-emitting elements ED may be transferred onto the plurality of banks BNK. The plurality of banks BNK may be bank patterns, structures, etc., but the embodiments of the present disclosure are not limited thereto.

A bank BNK of the first sub-pixel SP1, a bank BNK of the second sub-pixel SP2, and a bank BNK of the third sub-pixel SP3 may be disposed to be spaced apart from each other. The bank BNK of the first sub-pixel SP1, the bank BNK of the second sub-pixel SP2, and the bank BNK of the third sub-pixel SP3 may be formed separately. Accordingly, the banks BNK of the first sub-pixel SP1, the second sub-pixel SP2, and the third sub-pixel SP3 onto which different types of light-emitting elements ED are transferred can be easily identified.

A bank BNK of the 1-1 sub-pixel SP1a and a bank BNK of the 1-2 sub-pixel SP1b may be connected and formed to be spaced apart from each other or formed separately. For example, considering the transfer process design requirements and the like, the bank BNK of the 1-1 sub-pixel SP1a and the bank BNK of the 1-2 sub-pixel SP1b in which the light-emitting element ED of the same type is disposed may be connected and formed to be spaced apart from each other or formed separately. In addition, a bank BNK of the 2-1 sub-pixel SP2a and a bank BNK of the 2-2 sub-pixel SP2b may be connected or formed to be spaced apart from each other or formed separately. A bank BNK of the 3-1 sub-pixel SP3a and a bank BNK of the 3-2 sub-pixel SP3b may be connected or formed to be spaced apart from each other or formed separately. Accordingly, the banks BNK of the pair of the first sub-pixels SP1, the banks BNK of the pair of the second sub-pixels SP2, and the banks BNK of the pair of the third sub-pixels SP3 may be formed in various ways, and the embodiments of the present disclosure are not limited thereto.

For example, the plurality of banks BNK may be formed of an organic insulation material. The plurality of banks BNK may be formed of a single layer or multiple layers of an organic insulation material. For example, the plurality of banks BNK may be formed of a photoresist, polyimide (PI), or acrylic-based material, but the embodiments of the present disclosure are not limited thereto.

The first electrode CE1 may be disposed in each of the plurality of sub-pixels. The first electrode CE1 may be disposed on the bank BNK. The first electrode CE1 may be electrically connected to one of the plurality of signal lines TL. At least a part of the first electrode CE1 may extend outward of the bank BNK and may be electrically connected to the signal line TL closest to the first electrode CE1. For example, a part of the first electrode CE1 of the 1-1 sub-pixel SP1a may extend to one area of the 1-1 sub-pixel SP1a and may be electrically connected to the first signal line TL1, and a part of the first electrode CE1 of the 1-2 sub-pixel SP1b may extend to one area of the 1-2 sub-pixel SP1b and may be electrically connected to the second signal line TL2. A part of the first electrode CE1 of the 2-1 sub-pixel SP2a may extend to one area of the 2-1 sub-pixel SP2a and may be electrically connected to the third signal line TL3, and a part of the first electrode CE1 of the 2-2 sub-pixel SP2b may extend to one area of the 2-2 sub-pixel SP2b and may be electrically connected to the fourth signal line TL4. A part of the first electrode CE1 of the 3-1 sub-pixel SP3a may extend to one area of the 3-1 sub-pixel SP3a and may be electrically connected to the fifth signal line TL5, and a part of the first electrode CE1 of the 3-2 sub-pixel SP3b may extend to one area of the 3-2 sub-pixel SP3b and may be electrically connected to the sixth signal line TL6.

The first electrode CE1 may be electrically connected to the anode electrode 134 of the light-emitting element ED and may transmit the anode voltage from the pixel driving circuit PD to the light-emitting element ED through the signal line TL. A different voltage may be applied to the first electrode CE1 of each of the plurality of sub-pixels according to a video, which will be displayed. For example, a different voltage may be applied to the first electrode CE1 of each of the plurality of sub-pixels. Accordingly, the first electrode CE1 may be a pixel electrode, and the embodiments of the present disclosure are not limited thereto.

The first electrode CE1 may be formed of a conductive material. For example, the first electrodes CE1 may be formed integrally with the plurality of signal lines TL. For example, the first electrode CE1 may be formed of the same conductive material as the plurality of signal lines TL, but the embodiments of the present disclosure are not limited thereto. For example, the first electrode CE1 may be formed of a conductive material, such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but the embodiments of the present disclosure are not limited thereto. As another example, the plurality of first electrodes CE1 may be formed in a multilayered structure of the conductive material. For example, the plurality of first electrodes CE1 may be formed in a multilayered structure of titanium (Ti)/aluminum (Al)/indium tin oxide (ITO), but the embodiments of the present disclosure are not limited thereto.

The light-emitting element ED may be disposed in each of the plurality of sub-pixels. The plurality of light-emitting elements ED may be one of an LED or a micro LED, but the embodiments of the present disclosure are not limited thereto. The plurality of light-emitting elements ED may be disposed on the bank BNK and the first electrode CE1. The plurality of light-emitting elements ED may be disposed on the first electrode CE1 and electrically connected to the first electrode CE1. Accordingly, the light-emitting element ED may receive the anode voltage from the pixel driving circuit PD through the signal line TL and the first electrode CE1 and emit light.

The plurality of light-emitting elements ED may include a first light-emitting element 130, a second light-emitting element 140, and a third light-emitting element 150. The first light-emitting element 130 may be disposed in the first sub-pixel SP1. The second light-emitting element 140 may be disposed in the second sub-pixel SP2. The third light-emitting element 150 may be disposed in the third sub-pixel SP3. For example, one of the first light-emitting element 130, the second light-emitting element 140, and the third light-emitting element 150 may be a red light-emitting element, another may be a green light-emitting element, and the remaining one may be a blue light-emitting element, but the embodiments of the present disclosure are not limited thereto. Accordingly, red light, green light, and blue light emitted from the plurality of light-emitting elements ED may be combined to implement various colors of light including white. The types of the plurality of light-emitting elements ED are illustrative, and the embodiments of the present disclosure are not limited thereto.

The first light-emitting element 130 may include a 1-1 light-emitting element 130a disposed in the 1-1 sub-pixel SP1a, and a 1-2 light-emitting element 130b disposed in the 1-2 sub-pixel SP1b. The second light-emitting element 140 may include a 2-1 light-emitting element 140a disposed in the 2-1 sub-pixel SP2a, and a 2-2 light-emitting element 140b disposed in the 2-2 sub-pixel SP2b. The third light-emitting element 150 may include a 3-1 light-emitting element 150a disposed in the 3-1 sub-pixel SP3a, and a 3-2 light-emitting element 150b disposed in the 3-2 sub-pixel SP3b.

Referring to FIGS. 5, 6, 7, and 9 together, the second electrode CE2 may be disposed in each of the plurality of sub-pixels. The second electrode CE2 may be disposed on the light-emitting element ED. The second electrode CE2 may be electrically connected to the pixel driving circuit PD through a plurality of contact electrodes CCE.

For example, the second electrode CE2 may be electrically connected to a cathode electrode 135 of the light-emitting element ED to transmit a cathode voltage from the pixel driving circuit PD to the light-emitting element ED. The same cathode voltage may be applied to the second electrode CE2 of each of the plurality of sub-pixels. For example, the same voltage may be applied to the second electrode CE2 of each of the plurality of sub-pixels and the cathode electrode 135 of the light-emitting element ED. Accordingly, the second electrode CE2 may be a common electrode, and the embodiments of the present disclosure are not limited thereto.

At least some of the plurality of sub-pixels may share the second electrode CE2. At least some of the second electrodes CE2 of the plurality of sub-pixels may be electrically connected. Since the same voltage is applied to the second electrodes CE2, the second electrodes CE2 of at least some sub-pixels may be shared and used. For example, the second electrodes CE2 of at least some pixels PX among the plurality of pixels PX disposed in the same row may be connected. For example, one second electrode CE2 may be disposed in each of the plurality of pixels PX. One second electrode CE2 may be disposed per n sub-pixels.

For example, some of the second electrodes CE2 of the plurality of sub-pixels may be disposed to be spaced apart from each other or disposed separately. For example, second electrodes CE2 connected to pixels PX in an nth row and second electrodes CE2 connected to pixels PX in an (n+1)th row may be disposed to be spaced apart from each other or disposed separately. For example, the plurality of second electrodes CE2 may be disposed to be spaced apart from each other with the plurality of communication lines NL extending in the row direction interposed therebetween. Accordingly, the number of plurality of sub-pixels may be more than the number of plurality of second electrodes CE2. As another example, all of the second electrodes CE2 of the plurality of sub-pixels may be connected so that only one second electrode CE2 may be disposed on the substrate 110, and the embodiments of the present disclosure are not limited thereto.

The plurality of second electrodes CE2 may be formed of a transparent conductive material, but the embodiments of the present disclosure are not limited thereto. The plurality of second electrodes CE2 may be formed of a transparent conductive material so that light emitted from the light-emitting element ED may emit upward of the second electrodes CE2. For example, the second electrode CE2 may be formed of a transparent conductive material, such as indium tin oxide (ITO), indium zinc oxide (IZO), indium gallium zinc oxide (IGZO), etc., but the embodiments of the present disclosure are not limited thereto.

The plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2 to transmit the cathode voltage from the pixel driving circuit PD to the second electrode CE2.

For example, when a micro LED is used as the light-emitting element ED, the display apparatus 1000 may be manufacturing by forming a plurality of micro LED on a wafer and transferring the micro LED onto the substrate 110 of the display apparatus 1000. During the process of transferring the plurality of light-emitting elements ED having a micro size from the wafer onto the substrate 110, various types of defects may occur. For example, a non-transfer defect in which the light-emitting element ED is not transferred may occur in some sub-pixels, and a defect in which the light-emitting element ED is transferred out of a correct location due to an alignment error may occur in other sub-pixels. In addition, the transfer process may be performed normally, but the transferred light-emitting element ED may be defective. Accordingly, in consideration of defects during the transfer process of the plurality of light-emitting elements ED, the plurality of light-emitting elements ED of the same type may be transferred onto one sub-pixel. A lighting test of the plurality of light-emitting elements ED may be performed, and only one light-emitting element ED that is ultimately determined to be normal may be used.

For example, both the 1-1 light-emitting element 130a and the 1-2 light-emitting element 130b may be transferred onto one pixel PX, and whether the 1-1 light-emitting element 130a and the 1-2 light-emitting element 130b are defective may be tested. When it is determined that both the 1-1 light-emitting element 130a and the 1-2 light-emitting element 130b are normal, the 1-1 light-emitting element 130a may be used, and the 1-2 light-emitting element 130b may not be used. For another example, when it is determined that the 1-2 light-emitting element 130b among the 1-1 light-emitting element 130a and the 1-2 light-emitting element 130b are normal, the 1-1 light-emitting element 130a is not used, and the 1-2 light-emitting element 130b may be used. Accordingly, even when the plurality of light-emitting elements ED of the same type are transferred onto one pixel PX, only one light-emitting element ED may be eventually used.

Accordingly, one of the pair of light-emitting elements ED may be a main (or primary) light-emitting element ED, and the other may be a redundancy light-emitting element ED. The redundancy light-emitting element ED may be a spare light-emitting element ED used in detection of a defect of the main light-emitting element ED. When the main light-emitting element ED is defective, the defective main light-emitting element ED may be replaced with the redundancy light-emitting element ED; that is, the redundancy light-emitting element ED is used. Accordingly, by transferring both the main light-emitting element ED and the redundancy light-emitting element ED onto one pixel PX, it is possible to minimize or at least reduce the degradation of display quality due to the defects of the main light-emitting element ED and the redundancy light-emitting element ED.

For example, the 1-1 light-emitting element 130a, the 2-1 light-emitting element 140a, and the 3-1 light-emitting element 150a that are transferred onto one pixel PX may be used as the main light-emitting element ED, and the 1-2 light-emitting element 130b, the 2-2 light-emitting element 140b, and the 3-2 light-emitting element 150b that are transferred onto one pixel PX may be used as the redundancy light-emitting element ED.

FIG. 8 is a cross-sectional view of the display apparatus according to an embodiment of the present disclosure. FIG. 9 is a cross-sectional view of the display apparatus according to an embodiment of the present disclosure. For example, FIG. 8 is a cross-sectional view of the display area AA, the first non-display area NA1, the bending area BA, and the second non-display area NA2. For example, FIG. 8 is a cross-sectional view along line I-I′ in FIGS. 2 and 3. For example, FIG. 9 is a cross-sectional view of a display area including one sub-pixel SP1.

Referring to FIG. 8, a first buffer layer 111a and a second buffer layer 111b may be disposed in the remaining area of the substrate 110 not including the bending area BA.

The first buffer layer 111a and the second buffer layer 111b may be disposed in the display area AA, the first non-display area NA1, and the second non-display area NA2. The first buffer layer 111a and the second buffer layer 111b can reduce the penetration of moisture or impurities into the substrate 110. The first buffer layer 111a and the second buffer layer 111b may be formed of an inorganic insulation material. For example, the first buffer layer 111a and the second buffer layer 111b may be formed of a single layer or multiple layers of silicon oxide (SiOx) or silicon nitride (SiNx), but the embodiments of the present disclosure are not limited thereto.

For example, parts of the first buffer layer 111a and the second buffer layer 111b on the bending area BA may be removed. An upper surface of the substrate 110 located in the bending area BA may be exposed from the first buffer layer 111a and the second buffer layer 111b. By removing the first buffer layer 111a and the second buffer layer 111b, which are formed of an inorganic insulation material, from the bending area BA, it is possible to minimize or at least reduce cracks in the first buffer layer 111a and the second buffer layer 111b, which may occur during bending.

A plurality of alignment keys MK may be disposed between the first buffer layer 111a and the second buffer layer 111b. The plurality of alignment keys MK may be formed to identify the location of the pixel driving circuit PD during the manufacturing process of the display apparatus 1000. For example, the plurality of alignment keys MK may be formed to align the location of the pixel driving circuit PD transferred onto the adhesive layer 112. As another example, the plurality of alignment keys MK may be omitted.

The adhesive layer 112 may be disposed on the second buffer layer 111b. The adhesive layer 112 may be disposed in the display area AA, the first non-display area NA1, the bending area BA, and the second non-display area NA2. As another example, at least a part of the adhesive layer 112 may be removed from the non-display area NA including the bending area BA. For example, the adhesive layer 112 may be formed of one of an adhesive polymer, an epoxy resin, a UV-curable resin, a polyimide-based material, an acrylate-based material, a urethane-based material, and a polydimethylsiloxane (PDMS), but the embodiments of the present disclosure are not limited thereto.

The pixel driving circuit PD may be disposed on the adhesive layer 112 in the display area AA. When the pixel driving circuit PD is implemented as a driver, the driver may be mounted on the adhesive layer 112 by a transfer process, but the embodiments of the present disclosure are not limited thereto.

A first protective layer 113a and a second protective layer 113b may be disposed on the adhesive layer 112 and the pixel driving circuit PD. The first protective layer 113a and the second protective layer 113b may be disposed to surround side surfaces of the pixel driving circuit PD, but the embodiments of the present disclosure are not limited thereto. For example, the second protective layer 113b may be disposed to cover at least a part of the upper surface of the pixel driving circuit PD. For example, at least one of the first protective layer 113a and the second protective layer 113b that are disposed on the bending area BA may be omitted. For example, the first protective layer 113a may be entirely disposed in the display area AA and the non-display area NA, and a part of the second protective layer 113b may be disposed in the display area AA, the first non-display area NA1, and the second non-display area NA2. For example, a part of the second protective layer 113b in the bending area BA may be removed. However, the embodiments of the present disclosure are not limited thereto.

The first protective layer 113a and the second protective layer 113b may be formed of an organic insulation material, but the embodiments of the present disclosure are not limited thereto. For example, the first protective layer 113a and the second protective layer 113b may be formed of a photoresist, polyimide (PI), or photo acryl-based material, but the embodiments of the present disclosure are not limited thereto. For example, the first protective layer 113a and the second protective layer 113b may be an overcoating layer or an insulating layer, but the embodiments of the present disclosure are not limited thereto.

According to the present disclosure, a plurality of first connection lines 121 may be disposed on the second protective layer 113b in the display area AA. The plurality of first connection lines 121 may be lines for electrically connecting the pixel driving circuit PD to other components. For example, the pixel driving circuit PD may be electrically connected to the plurality of signal lines TL, the plurality of contact electrodes CCE, and the like through the plurality of first connection lines 121. For example, the plurality of first connection lines 121 may include a 1-1 connection line 121a, a 1-2 connection line 121b, a 1-3 connection line 121c, and a 1-4 connection line 121d, but the embodiments of the present disclosure are not limited thereto.

For example, the plurality of 1-1 connection lines 121a may be disposed on the second protective layer 113b. The plurality of 1-1 connection lines 121a may be electrically connected to the pixel driving circuit PD. The plurality of 1-1 connection lines 121a may transmit the voltage output from the pixel driving circuit PD to the first electrode CE1 or the second electrode CE2.

For example, the third protective layer 114 may be disposed on the second protective layer 113b. The third protective layer 114 may be disposed across the display area AA and the non-display area NA. In the bending area BA, the third protective layer 114 may cover side surfaces of the second protective layer 113b and an upper surface of the first protective layer 113a. The third protective layer 114 may be formed of an organic insulation material. For example, the third protective layer 114 may be formed of a photoresist, polyimide (PI), or photo acryl-based material, but the embodiments of the present disclosure are not limited thereto. For example, the first protective layer 113a, the second protective layer 113b, and the third protective layer 114 may be formed of the same material. The embodiments of the present disclosure are not limited thereto.

The plurality of 1-2 connection lines 121b may be disposed on the third protective layer 114. The plurality of 1-2 connection lines 121b may be connected or directly connected to the pixel driving circuit PD. For example, a part of the 1-2 connection line 121b may be directly connected to the pixel driving circuit PD through a contact hole of the third protective layer 114. The other part of the 1-2 connection line 121b may be electrically connected to the 1-1 connection line 121a through a contact hole of the third protective layer 114. However, the embodiments of the present disclosure are not limited thereto. The voltage output from the pixel driving circuit PD may be transmitted to the first electrode CE1 or the second electrode CE2 through the plurality of 1-2 connection lines 121b and other connection lines.

A first insulating layer 115a may be disposed on the plurality of 1-2 connection lines 121b. The first insulating layer 115a may be disposed across the display area AA and the non-display area NA, but the embodiments of the present disclosure are not limited thereto. The first insulating layer 115a may be formed of an organic insulation material, but the embodiments of the present disclosure are not limited thereto. For example, the first insulating layer 115a may be formed of a photoresist, polyimide (PI), or photo acryl-based material, but the embodiments of the present disclosure are not limited thereto.

The plurality of 1-3 connection lines 121c may be disposed on the first insulating layer 115a. The plurality of 1-3 connection lines 121c may be electrically connected to the plurality of 1-2 connection lines 121b. For example, the 1-3 connection line 121c may be electrically connected to the 1-2 connection line 121b through a contact hole of the first insulating layer 115a.

A second insulating layer 115b may be disposed on the plurality of the 1-3 connection lines 121c. The second insulating layer 115b may be disposed in the remaining area not including the bending area BA, but the embodiments of the present disclosure are not limited thereto. The second insulating layer 115b may be disposed in the display area AA, the first non-display area NA1, and the second non-display area NA2, but the embodiments of the present disclosure are not limited thereto. For example, a part of the second insulating layer 115b disposed in the bending area BA may be removed. The second insulating layer 115b may be formed of an organic insulation material, but the embodiments of the present disclosure are not limited thereto. For example, the second insulating layer 115b may be formed of a photoresist, polyimide (PI), or photo acryl-based material, but the embodiments of the present disclosure are not limited thereto.

A plurality of 1-4 connection lines 121d may be disposed on the second insulating layer 115b. The plurality of 1-4 connection lines 121d may be electrically connected to the plurality of 1-3 connection lines 121c. For example, the plurality of 1-4 connection lines 121d may be electrically connected to the 1-3 connection line 121c through contact holes of the second insulating layer 115b.

According to the present disclosure, a plurality of second connection lines 122 may be disposed on the second protective layer 113b in the non-display area NA. The plurality of second connection lines 122 may be lines for transmitting signals transmitted from the flexible circuit board (or the flexible film) 157 and the printed circuit board 160 (see FIG. 1) to the pad part PAD to the pixel driving circuit PD of the display area AA. For example, the plurality of second connection lines 122 may be electrically connected to the plurality of pad electrodes PE to receive signals from the flexible circuit board (or the flexible film) 157 and the printed circuit board.

For example, the plurality of second connection lines 122 may extend from the pad part PAD toward the display area AA to transmit signals to lines of the display area AA. In this case, the plurality of second connection lines 122 may serve as the link lines LL. The plurality of second connection lines 122 may include a 2-1 connection line 122a, a 2-2 connection line 122b, a 2-3 connection line 122c, and a 2-4 connection line 122d.

A plurality of 2-1 connection lines 122a may be disposed on the second protective layer 113b. The plurality of 2-1 connection lines 122a may extend from the second non-display area NA2 to the bending area BA and the first non-display area NA1. The plurality of 2-1 connection lines 122a may transmit the signals transmitted from the flexible circuit board (or the flexible film) 157 and the printed circuit board to the pad part PAD to the pixel driving circuit PD of the display area AA. The 2-1 connection line 122a may be electrically connected to the pixel driving circuit PD through the first connection line 121 of the display area AA. In addition, the 2-1 connection line 122a may be electrically connected to the second electrode CE2 through the first connection line 121 and the contact electrode CCE of the display area AA.

The plurality of 2-2 connection lines 122b may be disposed on the third protective layer 114. The plurality of 2-2 connection lines 122b may be disposed in the second non-display area NA2. The 2-2 connection line 122b may be electrically connected to the 2-1 connection line 122a through a contact hole of the third protective layer 114. Accordingly, the signals output from the flexible circuit board (or the flexible film) 157 and the printed circuit board may be transmitted to the 2-1 connection line 122a through the 2-2 connection line 122b.

The 2-3 connection line 122c may be disposed on the first insulating layer 115a. The 2-3 connection line 122c may be disposed in the second non-display area NA2. The 2-3 connection line 122c may be electrically connected to the 2-2 connection line 122b through a contact hole of the first insulating layer 115a. Accordingly, the signals output from the flexible circuit board (or the flexible film) 157 and the printed circuit board may be transmitted to the 2-1 connection line 122a through the 2-3 connection line 122c and the 2-2 connection line 122b.

The 2-4 connection line 122d may be disposed on the second insulating layer 115b. The 2-4 connection line 122d may be disposed in the second non-display area NA2. The 2-4 connection line 122d may be electrically connected to the 2-3 connection line 122c through a contact hole of the second insulating layer 115b. Accordingly, the signals output from the flexible circuit board (or flexible film) 157 and the printed circuit board may be transmitted to the 2-1 connection line 122a through the 2-4 connection line 122d, the 2-3 connection line 122c, and the 2-2 connection line 122b.

The plurality of first connection lines 121 and the plurality of second connection lines 122 may be formed of an excellent flexible conductive material or one of various conductive materials used in the display area AA. For example, the second connection line 122 of which a part is disposed in the bending area BA may be formed of an excellent flexible conductive material, such as gold (Au), silver (Ag), aluminum (Al), etc., but the embodiments of the present disclosure are not limited thereto. As another example, the plurality of first connection lines 121 and the plurality of second connection lines 122 may be formed of molybdenum (Mo), chromium (Cr), titanium (Ti), nickel (Ni), neodymium (Nd), copper (Cu), and an alloy of silver (Ag) and magnesium (Mg), or an alloy thereof, but the embodiments of the present disclosure are not limited thereto.

The third insulating layer 115c may be disposed on the plurality of first connection lines 121 and the plurality of second connection lines 122. The third insulating layer 115c may be disposed in the remaining area not including the bending area BA, but the embodiments of the present disclosure are not limited thereto. The third insulating layer 115c may be disposed in the display area AA, the first non-display area NA1, and the second non-display area NA2. A part of the third insulating layer 115c in the bending area BA may be removed. The third insulating layer 115c may be formed of an organic insulation material, but the embodiments of the present disclosure are not limited thereto. For example, the third insulating layer 115c may be formed of a photoresist, polyimide (PI), or photo acryl-based material, but the embodiments of the present disclosure are not limited thereto.

A plurality of banks BNK may be disposed on the third insulating layer 115c in the display area AA. The plurality of banks BNK may be disposed to overlap the plurality of sub-pixels, respectively. One or more light-emitting elements ED of the same type may be disposed on each of the plurality of banks BNK.

The plurality of signal lines TL may be disposed on the third insulating layer 115c in the display area AA. The plurality of signal lines TL may be disposed in an area between the plurality of banks BNK. For example, the plurality of signal lines TL may be disposed adjacent to one of the plurality of banks BNK.

The plurality of contact electrodes CCE may be disposed on the third insulating layer 115c in the display area AA. The plurality of contact electrodes CCE may supply the cathode voltage from the pixel driving circuit PD to the second electrode CE2.

The first electrode CE1 may be disposed on the bank BNK. For example, the first electrode CE1 may be disposed to extend from an adjacent signal line TL toward an upper portion of the bank BNK. The first electrode CE1 may be disposed on an upper surface of the bank BNK and side surfaces of the bank BNK. For example, the first electrode CE1 may be disposed to extend from the signal line TL on the upper surface of the third insulating layer 115c to the side surfaces of the bank BNK and the upper surface of the bank BNK.

Referring to FIG. 9, the first electrode CE1 may be formed of a plurality of conductive layers. For example, the first electrode CE1 may include a first conductive layer CE1a, a second conductive layer CE1b, a third conductive layer CE1c, and a fourth conductive layer CE1d, but the embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b, and the fourth conductive layer CE1d may be disposed on the third conductive layer CE1c. For example, each of the first conductive layer CE1a, the second conductive layer CE1b, the third conductive layer CE1c, and the fourth conductive layer CE1d may be formed of titanium (Ti), molybdenum (Mo), aluminum (Al), or titanium (Ti) and indium tin oxide (ITO), but the embodiments of the present disclosure are not limited thereto.

According to the present disclosure, among the plurality of conductive layers forming the first electrode CE1, some of the conductive layers, which have good reflection efficiency, may be formed as an alignment key for aligning the light-emitting element ED and/or a reflector. For example, the second conductive layer CE1b among the plurality of conductive layers of the first electrode CE1 may include a reflective material. For example, the second conductive layer CE1b may include aluminum (Al), but the embodiments of the present disclosure are not limited thereto. Accordingly, the second conductive layer CE1b may be formed as a reflector. In addition, due to the high reflection efficiency of the second conductive layer CE1b, the second conductive layer CE1b can be easily identified in the manufacturing process, and thus the location or transfer location of the light-emitting element ED may be aligned based on the second conductive layer CE1b.

For example, to form the second conductive layer CE1b as a reflector, parts of the third conductive layer CE1c and the fourth conductive layer CE1d that cover the second conductive layer CE1b may be removed or etched. For example, parts of the third conductive layer CE1c and the fourth conductive layer CE1d that are disposed on the bank BNK may be removed or etched to expose an upper surface of the second conductive layer CE1b. For example, central portions and border portions (or edge portions) of the third conductive layer CE1c and the fourth conductive layer CE1d, in which a solder pattern SDP is disposed may be left, and the remaining portions not including the central and border portions may be removed. For example, the border portion (or the edge portion) of each of the third conductive layer CE1c formed of titanium (Ti) and the fourth conductive layer CE1d formed of indium tin oxide (ITO) may not be etched. Accordingly, it is possible to prevent other conductive layers of the first electrode CE1 from being corroded by a tetramethylammonium hydroxide (TMAH) solution used in a mask process of the first electrode CE1.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which has high adhesion to the solder pattern SDP, corrosion resistance, and acid resistance. However, the embodiments of the present disclosure are not limited thereto.

The first conductive layer CE1a, the second conductive layer CE1b, the third conductive layer CE1c, and the fourth conductive layer CE1d may be sequentially deposited and then patterned by performing a photolithography process and an etching process, but the embodiments of the present disclosure are not limited thereto.

According to the present disclosure, the signal line TL, the contact electrode CCE, and the pad electrode PE that are disposed on the same layer as the first electrode CE1 may be formed in multiple conductive layers, but the embodiments of the present disclosure are not limited thereto. For example, the signal line TL, the contact electrode CCE, and the pad electrode PE may be formed in multiple layers of indium tin oxide (ITO)/titanium (Ti)/aluminum (Al)/titanium (Ti), but the embodiments of the present disclosure are not limited thereto.

According to the present disclosure, the solder pattern SDP may be disposed on the first electrode CE1 in each of the plurality of sub-pixels. The solder pattern SDP may bond the light-emitting element ED to the first electrode CE1. The first electrode CE1 and the light-emitting element ED may be electrically connected through eutectic bonding using the solder pattern SDP, but the embodiments of the present disclosure are not limited thereto. For example, when the solder pattern SDP is formed of indium (In) and the anode electrode 134 of the light-emitting element ED is formed of gold (Au), the solder pattern SDP and the anode electrode 134 may be bonded by applying heat and pressure during the transfer process of the light-emitting element ED. The light-emitting element ED may be bonded to the solder pattern SDP and the first electrode CE1 without a separate adhesive through eutectic bonding. For example, the solder pattern SDP may be formed of indium (In), tin (Sn), or an alloy thereof, but the embodiments of the present disclosure are not limited thereto. For example, the solder pattern SDP may be a bonding pad, etc., but the embodiments of the present disclosure are not limited thereto.

According to the present disclosure, a passivation layer 116 may be disposed on the plurality of signal lines TL, the plurality of first electrodes CE1, the plurality of contact electrodes CCE, and the third insulating layer 115c. For example, the passivation layer 116 may be disposed in the display area AA, the first non-display area NA1, and the second non-display area NA2. A part of the passivation layer 116, which is disposed in the bending area BA, may be removed. The part of the passivation layer 116 covering the plurality of pad electrodes PE in the second non-display area NA2 may be removed. Since the passivation layer 116 is disposed to cover the remaining area not including the bending area BA and the area in which the plurality of pad electrodes PE and the solder pattern SDP are disposed, it is possible to reduce the penetration of moisture or impurities into the light-emitting element ED. For example, the passivation layer 116 may be formed of a single layer or multiple layers of silicon oxide (SiOx) or silicon nitride (SiNx), but the embodiments of the present disclosure are not limited thereto. For example, the passivation layer 116 may be a protective layer, an insulating layer, etc., but the embodiments of the present disclosure are not limited thereto. For example, the passivation layer 116 may include a hole exposing the solder pattern SDP.

The light-emitting element ED may be disposed on the solder pattern SDP in each of the plurality of sub-pixels. The first light-emitting element 130 may be disposed in the first sub-pixel SP1. The second light-emitting element 140 may be disposed in the second sub-pixel SP2. The third light-emitting element 150 may be disposed in the third sub-pixel SP3.

The light-emitting element ED may be formed on a silicon wafer by a method of metal organic chemical vapor deposition (MOCVD), CVD, plasma-enhanced CVD (PECVD), molecular beam epitaxy (MBE), hydride vapor phase epitaxy (HVPE), sputtering, etc., but the embodiments of the present disclosure are not limited thereto.

Referring to FIG. 9, the first light-emitting element 130 may include the anode electrode 134, a first semiconductor layer 131, an active layer 132, a second semiconductor layer 133, the cathode electrode 135, and an encapsulation film 136, but the embodiments of the present disclosure are not limited thereto. For example, the encapsulation film 136 may not be included in the first light-emitting element 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be formed of a compound semiconductor of group III-V, group II-VI, etc. and may be doped with an impurity (or a dopant). For example, one of the first semiconductor layer 131 and the second semiconductor layer 133 may be a semiconductor layer doped with an n-type impurity, and the other may be a semiconductor layer doped with a p-type impurity, but the embodiments of the present disclosure are not limited thereto. For example, at least one of the first semiconductor layer 131 and the second semiconductor layer 133 may be a layer formed of a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), gallium arsenide (GaAs), etc., coated with an n-type or p-type impurity, but the embodiments of the present disclosure are not limited thereto. For example, the n-type impurity may be silicon (Si), germanium (Ge), selenium (Se), carbon (C), tellurium (Te), tin (Sn), etc., but the embodiments of the present disclosure are not limited thereto. For example, the p-type impurity may be magnesium (Mg), zinc (Zn), calcium (Ca), strontium (Sr), barium (Ba), beryllium (Be), or the like, but the embodiments of the present disclosure are not limited thereto.

For example, the first semiconductor layer 131 and the second semiconductor layer 133 may be a nitride semiconductor including an n-type impurity and a nitride semiconductor including a p-type impurity, respectively, but the embodiments of the present disclosure are not limited thereto. For example, the first semiconductor layer 131 may be a nitride semiconductor including a p-type impurity, and the second semiconductor layer 133 may be a nitride semiconductor including an n-type impurity, but the embodiments of the present disclosure are not limited thereto.

The active layer 132 may be disposed between the first semiconductor layer 131 and the second semiconductor layer 133. The active layer 132 may receive holes and electrons from the first semiconductor layer 131 and the second semiconductor layer 133 and emit light. For example, the active layer 132 may be formed in one of a single well structure, a multi-well structure, a single quantum well structure, a multi-quantum well (MQW) structure, a quantum dot structure, and a quantum wire structure, but the embodiments of the present disclosure are not limited thereto. For example, the active layer 132 may be formed of indium gallium nitride (InGaN), gallium nitride (GaN), etc., but the embodiments of the present disclosure are not limited thereto.

For another example, the active layer 132 may include a MQW structure having a well layer and a barrier layer having a greater band gap than the well layer. For example, the active layer 132 may have an InGaN layer as the well layer and an AlGaN layer as the barrier layer, but the embodiments of the present disclosure are not limited thereto.

The anode electrode 134 may be disposed between the first semiconductor layer 131 and the solder pattern SDP. For example, the anode electrode 134 may electrically connect the first semiconductor layer 131 to the first electrode CE1. The anode voltage output from the pixel driving circuit PD may be applied to the first semiconductor layer 131 through the signal line TL, the first electrode CE1, and the anode electrode 134. For example, the anode electrode 134 may be formed of a conductive material capable of eutectic bonding with the solder pattern SDP, but the embodiments of the present disclosure are not limited thereto. For example, the anode electrode 134 may be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), an alloy thereof, etc., but the embodiments of the present disclosure are not limited thereto.

The cathode electrode 135 may be disposed on the second semiconductor layer 133. For example, the cathode electrode 135 may electrically connect the second semiconductor layer 133 to the second electrode CE2. The cathode voltage output from the pixel driving circuit PD may be applied to the second semiconductor layer 133 through the contact electrode CCE, the second electrode CE2, and the cathode electrode 135. The cathode electrode 135 may be formed of a transparent conductive material so that light emitted from the light-emitting element ED may emit upward with respect to the light-emitting element ED, but the embodiments of the present disclosure are not limited thereto. For example, the cathode electrode 135 may be formed of a material, such as indium tin oxide (ITO), indium zinc oxide (IZO), indium gallium zinc oxide (IGZO), etc., but the embodiments of the present disclosure are not limited thereto.

The encapsulation film 136 may be disposed on at least parts of the first semiconductor layer 131, the active layer 132, the second semiconductor layer 133, the anode electrode 134, and the cathode electrode 135. For example, the encapsulation film 136 may surround the at least parts of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may surround side surfaces of the first semiconductor layer 131, side surfaces of the active layer 132, and side surfaces of the second semiconductor layer 133.

For example, the encapsulation film 136 may be disposed on at least parts of the anode electrode 134 and the cathode electrode 135, for example, an edge portion (or border portion or one side) of the anode electrode 134 and an edge portion (or border portion or one side) of the cathode electrode 135. At least a part of the anode electrode 134 may be exposed from the encapsulation film 136 to connect the anode electrode 134 to the solder pattern SDP. For example, at least a part of the cathode electrode 135 may be exposed from the encapsulation film 136 to connect the cathode electrode 135 to the second electrode CE2. For example, the encapsulation film 136 may be formed of an insulation material, such as silicon nitride (SiNx) or silicon oxide (SiOx), but the embodiments of the present disclosure are not limited thereto.

As another example, the encapsulation film 136 may have a structure in which a reflective material is dispersed in a resin layer, but the embodiments of the present disclosure are not limited thereto. For example, the encapsulation film 136 may be manufactured to be a reflector having various structures, but the embodiments of the present disclosure are not limited thereto. Light emitted from the active layer 132 may be reflected upward by the encapsulation film 136, thereby increasing light extraction efficiency. For example, the encapsulation film 136 may be a reflective layer, but the embodiments of the present disclosure are not limited thereto.

According to the present disclosure, the light-emitting element ED has been described as having a vertical structure, but the embodiments of the present disclosure are not limited thereto. For example, the light-emitting element ED may have a lateral structure or a flip chip structure.

The first light-emitting element 130 has been described with reference to FIG. 9, but the second light-emitting element 140 and the third light-emitting element 150 may have substantially the same structure as the first light-emitting element 130. For example, each of the second light-emitting element 140 and the third light-emitting element 150 may have substantially the same structure as the first light-emitting element 130, i.e., including the first semiconductor layer 131, the active layer 132, the second semiconductor layer 133, the anode electrode 134, the cathode electrode 135, and the encapsulation film 136 of the first light-emitting element 130.

According to the present disclosure, a first optical layer 117a may be disposed to surround the plurality of light-emitting elements ED in the display area AA. For example, the first optical layer 117a may be disposed to cover the plurality of light-emitting elements ED and banks BNK in areas of the plurality of sub-pixels. For example, the first optical layer 117a may cover the bank BNK, a part of the passivation layer 116, and the plurality of light-emitting elements ED. The first optical layer 117a may be disposed between the plurality of light-emitting elements ED and between the plurality of banks BNK that are included in one pixel PX or cover the plurality of light-emitting element ED and the plurality of banks BNK. For example, the first optical layers 117a may be disposed to extend in a first direction X and to be spaced apart from each other in a second direction Y. For example, the first optical layer 117a may be disposed to surround the side portions of the light-emitting element ED and the bank BNK between the passivation layer 116 and the second electrode CE2, but the embodiments of the present disclosure are not limited thereto. For example, the first optical layer 117a may be a diffusion layer, a sidewall diffusion layer, etc., but the embodiments of the present disclosure are not limited thereto.

The first optical layer 117a may include an organic insulation material having particles (especially, fine particles) dispersed therein, but the embodiments of the present disclosure are not limited thereto. For example, the first optical layer 117a may be formed of siloxane having fine metal particles, such as titanium dioxide (TiO2) particles, dispersed therein, but the embodiments of the present disclosure are not limited thereto. Light emitted from the plurality of light-emitting elements ED may be scattered by the fine particles dispersed in the first optical layer 117a and emitted to the outside of the display apparatus 1000. Accordingly, the first optical layer 117a can increase the extraction efficiency of the light emitted from the plurality of light-emitting elements ED.

For example, the first optical layer 117a may be disposed in each of the plurality of pixels PX and disposed together in some pixels PX disposed in the same row, but the embodiments of the present disclosure are not limited thereto. For example, the first optical layer 117a may be disposed in each of the plurality of pixels PX, or the plurality of pixels may share one first optical layer 117a. As another example, each of the plurality of sub-pixels may separately include the first optical layer 117a, but the embodiments of the present disclosure are not limited thereto.

According to the present disclosure, a second optical layer 117b may be disposed on the passivation layer 116 in the display area AA. For example, the second optical layer 117b may be disposed to surround the first optical layer 117a. For example, the second optical layer 117b may contact side surfaces of the first optical layer 117a. For example, the second optical layer 117b may be disposed in areas between the plurality of pixels PX. However, the embodiments of the present disclosure are not limited thereto. For example, the second optical layer 117b may be a diffusion layer, a diffusion layer window, a window diffusion layer, etc., but the embodiments of the present disclosure are not limited thereto.

The second optical layer 117b may be formed of an organic insulating layer, but the embodiments of the present disclosure are not limited thereto. The second optical layer 117b may be formed of the same material as the first optical layer 117a, but the embodiments of the present disclosure are not limited thereto. For example, the first optical layer 117a may include fine particles, and the second optical layer 117b may not include fine particles. For example, the second optical layer 117b may be formed of siloxane, but the embodiments of the present disclosure are not limited thereto.

For example, a thickness of the first optical layer 117a may be smaller than a thickness of the second optical layer 117b, but the embodiments of the present disclosure are not limited thereto. Accordingly, an area in which the first optical layer 117a is disposed may include a concave portion that is recessed inward lower than an upper surface of the second optical layer 117b in a plan view.

According to the present disclosure, the second electrode CE2 may be disposed on the first optical layer 117a and the second optical layer 117b. For example, the second electrode CE2 may be electrically connected to the plurality of contact electrodes CCE through contact holes of the second optical layer 117b. For example, the second electrode CE2 may be disposed on the plurality of light-emitting elements ED. For example, the second electrode CE2 may include a transparent conductive oxide, such as indium tin oxide (ITO), indium zinc oxide (IZO), etc., but the embodiments of the present disclosure are not limited thereto. For example, the second electrode CE2 may be disposed in contact with the cathode electrode 135. For example, the second electrode CE2 may overlap the first optical layer 117a. For example, the second electrode CE2 may cover a flat outer surface of the first optical layer 117a.

The second electrode CE2 may extend continuously in the first direction of the substrate 110. Accordingly, the second electrode CE2 may be connected in common to the plurality of pixels PX disposed in the first direction of the substrate 110.

For example, the second electrode CE2 may be connected in common to the plurality of pixels PX.

According to the present disclosure, the second electrode CE2 may continuously extend on the first optical layer 117a, the second optical layer 117b, and the light-emitting element ED. The area in which the first optical layer 117a is disposed may include the concave portion that is recessed inward lower than the upper surface of the second optical layer 117b. Accordingly, since a first portion of the second electrode CE2 disposed on the first optical layer 117a is disposed along the concave portion, the first portion may be disposed at a location lower than a second portion of the second electrode CE2 disposed on the second optical layer 117b.

A third optical layer 117c may be disposed on the second electrode CE2. The third optical layer 117c may be disposed to overlap the plurality of light-emitting elements ED and the first optical layer 117a. Since the third optical layer 117c is disposed above the second electrode CE2 and the plurality of light-emitting elements ED, it is possible to eliminate or at least reduce spots (mura) that may occur in some of the plurality of light-emitting elements ED. For example, when the plurality of light-emitting elements ED are transferred onto the substrate 110 of the display apparatus 1000, an area of which distances between the plurality of light-emitting elements ED are not uniform may occur due to a process deviation, etc. When the distances between the plurality of light-emitting elements ED are not uniform, a light-emitting area of each of the plurality of light-emitting elements ED may be disposed non-uniformly, thereby making spots (mura) visible to a user. Accordingly, since the third optical layer 117c to uniformly diffuse light above the plurality of light-emitting elements ED is formed, it is possible to reduce the light emitted from some light-emitting elements ED from being visible as spots. Accordingly, since the light emitted from the plurality of light-emitting elements ED is uniformly diffused by the third optical layer 117c and extracted to the outside of the display apparatus 1000, it is possible to improve the luminance uniformity of the display apparatus 1000.

The third optical layer 117c may be formed of an organic insulation material having particles (especially, fine particles) dispersed therein, but the embodiments of the present disclosure are not limited thereto. For example, the third optical layer 117c may be formed of siloxane having fine metal particles, such as titanium dioxide (TiO2) particles, dispersed therein, but the embodiments of the present disclosure are not limited thereto. For example, the third optical layer 117c may be formed of the same material as the first optical layer 117a, but the embodiments of the present disclosure are not limited thereto. For example, the third optical layer 117c may be a diffusion layer, an upper diffusion layer, etc., but the embodiments of the present disclosure are not limited thereto.

A refractive index of the third optical layer 117c may range from 1.50 to 1.55. In one example, the refractive index of the third optical layer 117c may be 1.53.

According to the present disclosure, the light emitted from the plurality of light-emitting elements ED may be scattered by fine particles dispersed in the third optical layer 117c and emitted to the outside of the display apparatus 1000. The third optical layer 117c may uniformly mix the light emitted from the plurality of light-emitting elements ED, thereby further improving the luminance uniformity of the display apparatus 1000. In addition, it is possible to increase the light extraction efficiency of the display apparatus 1000 by the light scattered from the fine particles, thereby enabling the low-power driving of the display apparatus 1000.

A black matrix BM may be disposed on the second electrode CE2, the first optical layer 117a, the second optical layer 117b, and the third optical layer 117c in the display area AA. For example, the black matrix BM may fill the contact hole of the second optical layer 117b. Since the black matrix BM is formed to cover the display area AA, it is possible to reduce color mixing of light of a plurality of sub-pixels and external light reflection. For example, since the black matrix BM is also disposed in the contact hole by which the second electrode CE2 and the contact electrode CCE are connected, it is possible to prevent light leakage between neighboring sub-pixels.

For example, the black matrix BM may be formed of an opaque material, but the embodiments of the present disclosure are not limited thereto. For example, the black matrix BM may be an organic insulation material to which a black pigment or black dye is added, but the embodiments of the present disclosure are not limited thereto.

A cover layer 118 may be disposed on the black matrix BM in the display area AA. The cover layer 118 may protect components under the cover layer 118. For example, the cover layer 118 may be formed of an organic insulation material, but the embodiments of the present disclosure are not limited thereto. For example, the cover layer 118 may be formed of a photoresist, polyimide (PI), or photo acryl-based material, but the embodiments of the present disclosure are not limited thereto. For example, the cover layer 118 may be an overcoating layer, an insulating layer, etc., but the embodiments of the present disclosure are not limited thereto.

The polarizing layer 293 may be disposed above the cover layer 118 via a first adhesive layer 291. The cover member 155 may be disposed above the polarizing layer 293 via a second adhesive layer 295. For example, the first adhesive layer 291 and the second adhesive layer 295 may include an OCA, an OCR, a PSA, etc., but the embodiments of the present disclosure are not limited thereto.

According to the present disclosure, the plurality of pad electrodes PE may be disposed on the third insulating layer 115c in the second non-display area NA2. For example, at least parts of the plurality of pad electrodes PE may be exposed with respect to the passivation layer 116. For example, the plurality of pad electrodes PE may be electrically connected to the 2-4 connection line 122d through a contact hole of the third insulating layer 115c.

An adhesive layer ACF may be disposed on the plurality of pad electrodes PE. The adhesive layer ACF may be an adhesive layer in which conductive balls are dispersed in an insulation material, but the embodiments of the present disclosure are not limited thereto. When heat or pressure is applied to the adhesive layer ACF, the conductive balls may be electrically connected at a portion in which the heat or pressure is applied, thereby providing conductive characteristics. The adhesive layer ACF may be disposed between the plurality of pad electrodes PE and the flexible circuit board (or the flexible film) 157 to attach or bond the flexible circuit board (or the flexible film) 157 to the plurality of pad electrodes PE. For example, the adhesive layer ACF may be an anisotropic conductive film (ACF), but the embodiments of the present disclosure are not limited thereto.

The flexible circuit board (or the flexible film) 157 may be disposed on the adhesive layer ACF. The flexible circuit board (or the flexible film) 157 may be electrically connected to the plurality of pad electrodes PE through the adhesive layer ACF. Accordingly, signals output from the flexible circuit board (or the flexible film) 157 and the printed circuit board may be transmitted to the pixel driving circuit PD of the display area AA through the plurality of pad electrodes PE, the 2-4 connection line 122d, the 2-3 connection line 122c, the 2-2 connection line 122b, and the 2-1 connection line 122a.

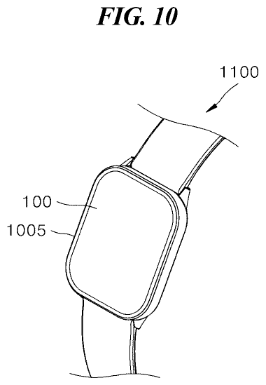

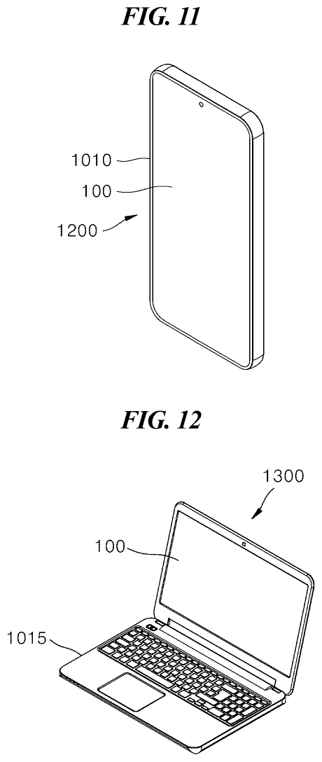

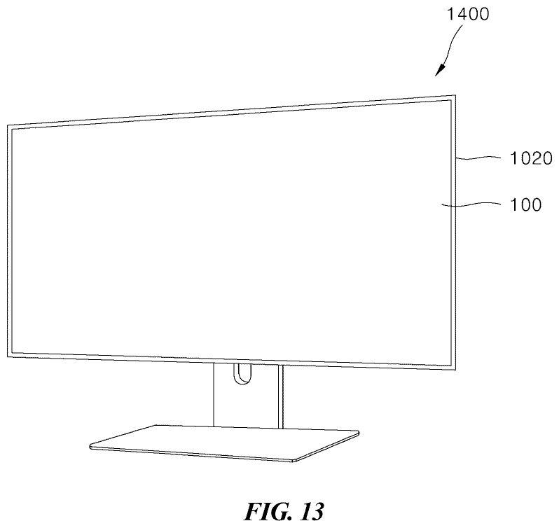

FIGS. 10 to 13 are views illustrating a device to which the display apparatus according to the embodiments of the present disclosure is applied.

Referring to FIGS. 10 to 13, the display apparatus 1000 according to embodiments of the present disclosure may be included in various devices or electronic devices. For example, referring to FIGS. 10 to 13, various electronic devices may include a wearable device 1100, a mobile device 1200, a notebook PC 1300, and a monitor or TV 1400, but the embodiments of the present disclosure are not limited thereto.

The wearable device 1100, the mobile device 1200, the notebook PC 1300, and the monitor or TV 1400 may respectively include case units 1005, 1010, 1015, and 1020, respectively, and the display panel 100 and the display apparatus 1000 according to the embodiments of the present disclosure, which are described in FIGS. 1 to 9.

For example, the display apparatus according to the embodiment of the present disclosure may be applied to a mobile device, a video phone, a smart watch, a watch phone, a wearable device, a foldable device, a rollable device, a bendable device, a flexible device, a curved device, a sliding device, a variable device, an electronic notebook, an e-book, a portable multimedia player (PMP), a personal digital assistant (PDA), an MP3 player, a mobile medical device, a desktop PC, a laptop PC, a netbook computer, a workstation, a navigation system, a vehicle display apparatus, a theater display apparatus, a television, a wallpaper device, a signage device, a game device, a laptop computer, a monitor, a camera, a camcorder, a home appliances, etc.

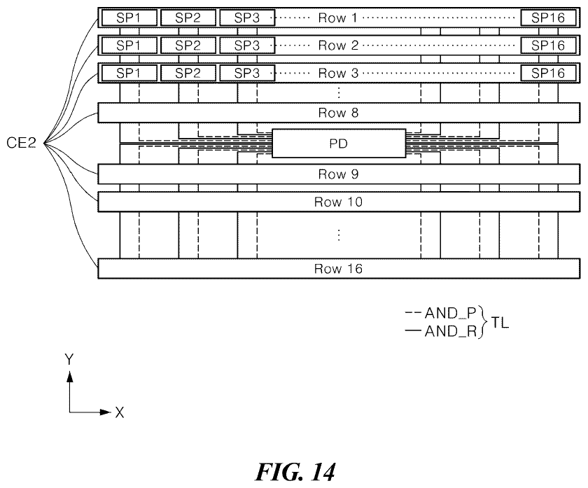

FIG. 14 is a plan view illustrating an area in which one of a plurality of pixel driving circuits is disposed according to one embodiment.

Referring to FIGS. 3, 5, and 14 together, one pixel driving circuit PD may be electrically connected to the plurality of signal lines TL electrically connected to the plurality of sub-pixels. The plurality of sub-pixels may include the plurality of light-emitting elements ED (see FIG. 5) disposed in the same column direction SP1, SP2, SP3, . . . , and SP16 and the same row direction Row1, Row2, Row3, . . . , and Row16.

The plurality of signal lines TL extending in the column direction may be disposed between the plurality of sub-pixels. The plurality of signal lines TL may include a first line AND_P and a second line AND_R. The first line AND_P and the second line AND_R may be disposed to be spaced apart from each other in the first direction X, that is, the row direction. The first line AND_P and the second line AND_R may be electrically connected to each of the pair of sub-pixels. The light-emitting element ED may be disposed in each of the pair of sub-pixels. One of the light-emitting elements ED may be a main light-emitting element, and the other may be a redundancy light-emitting element. For example, referring to FIG. 5, the 1-1 light-emitting element 130a, the 2-1 light-emitting element 140a, and the 3-1 light-emitting element 150a transferred onto one pixel PX may be main light-emitting elements ED. In addition, the 1-2 light-emitting element 130b, the 2-2 light-emitting element 140b, and the 3-2 light-emitting element 150b transferred onto one pixel PX may be redundancy light-emitting elements ED.

The first line AND_P may be a signal line disposed in an odd column. For example, referring to FIGS. 5 and 14 together, the first line AND_P may be the first signal line TL1, the third signal line TL3, and the fifth signal line TL5. The second line AND_R may be a signal line disposed in an even column. For example, the second line AND_R may be the second signal line TL2, the fourth signal line TL4, and the sixth signal line TL6. The first line AND_P and the second line AND_R may be referred to as signal lines.

The plurality of second electrodes CE2 may be disposed to extend in the row direction. Each of the plurality of second electrodes CE2 may be disposed to be spaced apart from each other in the second direction Y, that is, the column direction.

The plurality of signal lines TL connected to at least one pixel driving circuit PD may be radially connected to connect a first sub-pixel SP1 disposed at a first location of a first row Row1 to a sixteenth sub-pixel SP16 disposed opposite to the first sub-pixel SP1 and at a sixteenth location of the first row Row1 to the pixel driving circuit PD. For example, the shape in which the plurality of signal lines TL are connected may be a rhombus shape or a shape of a letter “T” in a plan view.

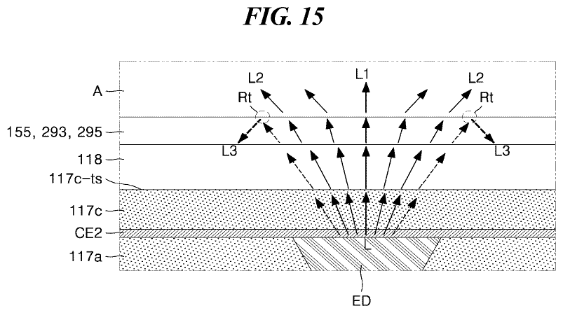

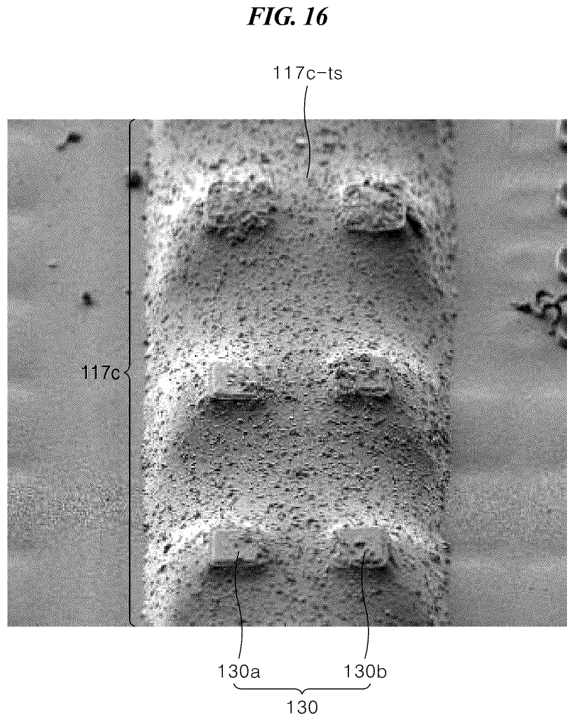

FIG. 15 is a cross-sectional view illustrating area “II” in FIG. 8 according to one embodiment. In addition, FIG. 16 is a view illustrating a third optical layer according to one embodiment of the present disclosure. In FIG. 16, the same components as those described with reference to FIG. 8 in FIG. 15 are denoted as the same reference numerals, and the descriptions thereof are simplified or omitted.

Referring to FIGS. 8 and 15 together, the cover layer 118 may be disposed on the black matrix BM and the third optical layer 117c. The polarizing layer 293 may be disposed on the cover layer 118 via the first adhesive layer 291. The cover member 155 may be disposed on the polarizing layer 293 via the second adhesive layer 295.

The cover layer 118 may include a transparent organic insulation material. For example, the cover layer 118 may include a photo acryl-based material, but is not limited thereto. The cover layer 118 may be referred to as an overcoating layer.

The cover layer 118 may cover at least areas in which the plurality of light-emitting elements ED are disposed. One surface of the cover layer 118 may be disposed in contact with the third optical layer 117c. The third optical layer 117c may include an organic insulation material having fine particles dispersed therein. For example, the fine particles may include titanium dioxide (TiO2) particles, but are not limited thereto. The organic insulation material may include a siloxane resin.

A refractive index of the third optical layer 117c may range from 1.50 to 1.55. In one example, the refractive index of the third optical layer 117c may be 1.53. The ranges of the refractive indexes of the cover layer 118, the polarizing layer 293, and the cover member 155 may be the range of the refractive index of the third optical layer 117c. For example, the refractive indexes of the cover layer 118, the polarizing layer 293, and the cover member 155 may range from 1.50 to 1.55.

The third optical layer 117c may scatter light incident from the plurality of light-emitting elements ED by the fine particles and emit the light to the outside. It is possible to increase the light extraction efficiency of the display apparatus by the light scattered from the fine particles. Accordingly, the display apparatus can be driven at lower power.

Referring to FIG. 16, an upper surface 117c-ts of the third optical layer 117c may have an uneven surface. For example, the upper surface 117c-ts of the third optical layer 117c may have a first surface roughness due to a plurality of unevennesses (e.g., uneven portions). The uneven upper surface 117c-ts of the third optical layer 117c can further increase the scattering of the light incident from the plurality of light-emitting elements ED due to the plurality of unevennesses. Accordingly, the scattered light may increase, thereby further increasing the light extraction efficiency of the display apparatus, and thus the display apparatus can be driven at low power.

In order for the upper surface 117c-ts of the third optical layer 117c to have an uneven surface, a temperature of a bake process may be controlled during a process for forming the third optical layer 117c. For example, a material for a third optical layer covering the light-emitting element ED is applied, and an exposure process of selectively leaving an area in which the third optical layer will be formed is performed. Subsequently, a development process is performed to remove other areas not including the area in which the third optical layer 117c is formed. Then, a hard bake process of removing a residual developer and an organic solvent is performed. In order for the upper surface 117c-ts of the third optical layer 117c to have an uneven surface, the hard bake process may perform heat treatment at a temperature of 170 degrees (° C.).

Light L emitted from the plurality of light-emitting elements ED that is a light source may be emitted (L1 and L2) to outside air A after passing through the third optical layer 117c, the cover layer 118, the polarizing layer 293, and the cover member 155.

Among the light L emitted from the light-emitting elements ED, the light L1 emitted from a central portion of a light-emitting surface may be emitted in a front direction of the polarizing layer 293. The light L2 having an inclination angle with respect to a surface of the light-emitting surface from the central portion to an edge of the light-emitting surface may be emitted.

Among the light emitted from the light-emitting elements ED and incident on each layer, light having an incident angle greater than a total reflection angle is not emitted to the outside but is extinguished by total internal reflection. For example, the total reflection angle may be 42 degrees) (°.

The range of the refractive index of each of the third optical layer 117c, the cover layer 118, the polarizing layer 293, and the cover member 155 may be similar or same. For example, the refractive index of each of the third optical layer 117c, the cover layer 118, the polarizing layer 293, and the cover member 155 may range from 1.50 to 1.55. Accordingly, the amount of light that is internally totally reflected among the light incident on an interface between the third optical layer 117c and the cover layer 118 and an interface between the cover layer 118 and the polarizing layer 293 may not be large.

In this regard, the refractive index of the external air A may be 1 that is smaller than the refractive index of each of the third optical layer 117c, the cover layer 118, the polarizing layer 293, and the cover member 155. Accordingly, a difference in refractive indices between the polarizing layer 293, the cover member 155, and the air A may be large. Accordingly, the light L emitted from the light emitting element ED may be refracted at a relatively greater angle than lower layers at the interface between the polarizing layer 293, the cover member 155, and the air A.

Among the light emitted from the light-emitting elements ED and incident on each layer, light having an incident angle greater than a total reflection angle of 42 degrees (°) is not emitted to the outside but is extinguished by total internal reflection. Among the light incident on the interface between the polarizing layer 293, the cover member 155, and the air A, light L3 refracted at a relatively greater slope than the lower layers and having an incident angle greater than 42 degrees (°) may be extinguished by total internal reflection Rt.

In this way, when the amount of light that is internally totally reflected at the interface between the polarizing layer 293, the cover member 155, and the air A increases, the amount of light extinguished increases, thereby reducing light extraction efficiency. When the light extraction efficiency is reduced, the quality of the display apparatus can be degraded.

Accordingly, to reduce the amount of light that is extinguished at the interface between the polarizing layer 293, the cover member 155, and the air A, the amount of internally totally reflected light can be reduced.

A display apparatus according to another embodiment of the present disclosure may include a component for reducing the amount of internally totally reflected light.

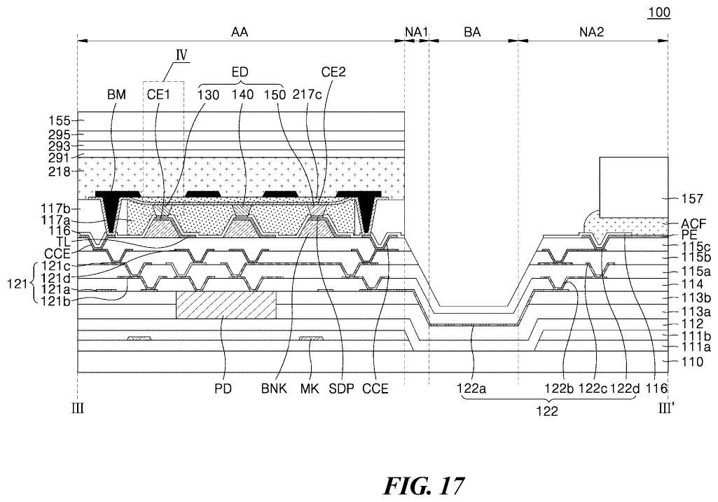

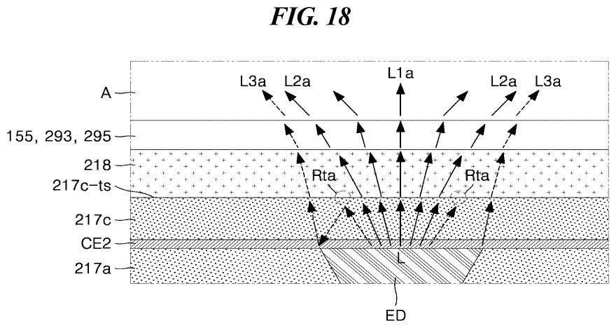

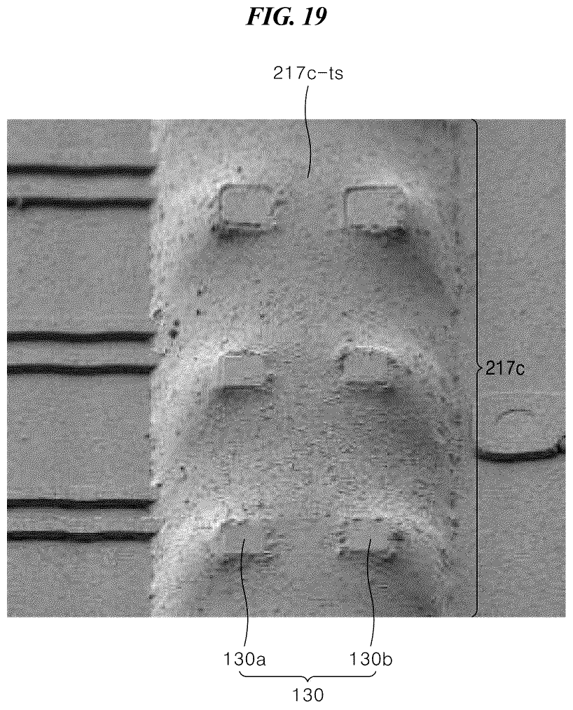

FIG. 17 is a cross-sectional view along line III-III′ in FIG. 2 according to another embodiment of the present disclosure. FIG. 18 is a cross-sectional view illustrating area “IV” in FIG. 17 according to one embodiment. In addition, FIG. 19 is a view illustrating a fourth optical layer according to another embodiment of the present disclosure. In FIGS. 17 to 19, the same components as those described with reference to FIG. 8 are denoted as the same reference numerals, and the descriptions thereof are simplified or omitted.

Referring to FIGS. 17 and 18 together, the cover layer 218 may be disposed above the black matrix BM and the fourth optical layer 217c. The polarizing layer 293 may be disposed above the cover layer 218 via the first adhesive layer 291. The cover member 155 may be disposed above the polarizing layer 293 via the second adhesive layer 295.

The fourth optical layer 217c may include an organic insulation material having particles (especially, fine particles) dispersed therein. For example, the fourth optical layer 217c may be formed of siloxane having fine metal particles, such as titanium dioxide (TiO2) particles, dispersed therein. The fourth optical layer 217c may be formed of the same material as the first optical layer 117a, but the embodiments of the present disclosure are not limited thereto.

A refractive index of the fourth optical layer 217c may range from 1.50 to 1.55. In one example, the refractive index of the fourth optical layer 217c may be 1.53.

Referring to FIG. 19 along with FIG. 16, an upper surface 217c-ts of the fourth optical layer 217c may have a second surface roughness that is relatively less uneven than the upper surface 117c-ts of the third optical layer 117c of FIG. 16. For example, the upper surface 217c-ts of the fourth optical layer 217c may have a relatively smoother surface than the upper surface 117c-ts of the third optical layer 117c of FIG. 16.

In order for the upper surface 217c-ts of the fourth optical layer 217c to have an uneven surface, a temperature of a bake process may be controlled during a process for forming the fourth optical layer 217c. For example, after the development process, a hard bake process of removing a residual developer and an organic solvent may be performed. In order for the upper surface 217c-ts of the fourth optical layer 217c to have a relatively smooth surface, the hard bake process may perform heat treatment at a relatively higher temperature than the hard bake process of the third optical layer 117c. For example, the hard bake process may be performed at a temperature of 230 degrees (° C.).

The fourth optical layer 217c may have a relatively smooth surface by having a second surface roughness that is reduced compared to the first surface roughness of the third optical layer 117c. The relatively smooth upper surface 217c-ts of the fourth optical layer 217c may increase total internal reflection of incident light at an interface between the fourth optical layer 217c and the cover layer 218.

The cover layer 218 may be disposed on the fourth optical layer 217c. The fourth optical layer 217c may come into contact with the cover layer 218. The cover layer 218 may include an organic insulation material. The cover layer 218 may include an organic insulation material having scattering particles dispersed therein. The organic insulation material may include a polymer insulation material. For example, the polymer insulation material may include an organosiloxane resin, and the scattering particles may include hollow silica. The hollow silica has a relatively low refractive index compared to particles of which the inside is filled due to an empty space that is present in a surface of the particle and inside the particle. Accordingly, the organosiloxane resin having the hollow silica dispersed therein may have a relatively low refractive index compared to a single material of the organosiloxane resin. However, the embodiments of the present disclosure are not limited thereto. For example, the cover layer 218 may include a transparent organic insulation material having a lower refractive index than the fourth optical layer 217c.

For example, the cover layer 218 may have a relatively smaller refractive index than the fourth optical layer 217c. The refractive index of the cover layer 218 may be smaller than 1.4. The refractive index of the cover layer 218 may range from 1.37 to 1.39. In one example, the refractive index of the cover layer 218 may be 1.38.

The light emitted from the plurality of light-emitting elements ED that is a light source may be emitted to the outside after passing through the fourth optical layer 217c, the cover layer 218, the polarizing layer 293, and the cover member 155.

Among the light incident on the polarizing layer 293, light having an incident angle greater than the total reflection angle is not emitted to the outside but is extinguished by total internal reflection. As the amount of light that is internally totally reflected in the polarizing layer 293 increases, the amount of light extinguished also increases, thereby reducing light extraction efficiency. Accordingly, the incident angle of the light incident on the polarizing layer 293 needs to be made smaller than the total reflection angle to reduce the amount of light that is internally totally reflected in the polarizing layer 293.

To this end, the cover layer 218 having a smaller refractive index than the fourth optical layer 217c may be disposed on the fourth optical layer 217c. When the cover layer 218 having a relatively lower refractive index than the fourth optical layer 217c is disposed, a ratio of light totally reflected at the interface can be increased. For example, the ratio of light totally reflected at the interface between the fourth optical layer 217c and the cover layer 218 can be increased.

Referring to FIG. 18, light L emitted from the plurality of light-emitting elements ED that is a light source may be emitted (L1a, L2a, and L3a) to outside air A after passing through the fourth optical layer 217c, the cover layer 218, the polarizing layer 293, and the cover member 155.

Among the light L emitted from the light-emitting elements ED, the light L1a emitted from a central portion of a light-emitting surface may be emitted in a front direction of the polarizing layer 293. The light L2a having an inclination angle with respect to a surface of the light-emitting surface from the central portion to an edge of the light-emitting surface may be emitted.

According to another embodiment of the present disclosure, the cover layer 218 having a relatively lower refractive index than the fourth optical layer 217c may be disposed on the fourth optical layer 217c. The range of the refractive index of each of the fourth optical layer 217c, the polarizing layer 293, and the cover member 155 may be similar or same. For example, the refractive index of each of the fourth optical layer 217c, the polarizing layer 293, and the cover member 155 may range from 1.50 to 1.55.

The refractive index of the cover layer 218 disposed on the fourth optical layer 217c may be less than 1.4. The refractive index of the cover layer 218 may range from 1.37 to 1.39. In one example, the refractive index of the cover layer 218 may be 1.38.

Accordingly, a difference in refractive indexes between the fourth optical layer 217c and the cover layer 218 may be large. For example, when the refractive index of the fourth optical layer 217c is more than 1.53 and the refractive index of the cover layer 218 is less than 1.38, the difference in refractive indexes between the two layers may be more than 0.15.

Accordingly, the light L emitted from the light emitting element ED may be refracted at a relatively great slope at the interface between the fourth optical layer 217c and the cover layer 218.

Among the light emitted from the light-emitting elements ED and incident on each layer, light having an incident angle greater than a total reflection angle of 42 degrees (°) is not emitted to the outside but is extinguished by total internal reflection. Light incident on the upper surface 217c-ts of the fourth optical layer, which is the interface between the fourth optical layer 217c and the cover layer 218, may be refracted at a relatively great slope than the lower layers, and light having an incident angle greater than 42 degrees (°) may be extinguished by total internal reflection Rta.

The light totally reflected at the interface between the fourth optical layer 217c and the cover layer 218 may be incident on the polarizing layer 293 through light recycling, such as a re-reflection process, etc. For example, the totally reflected light may be re-incident light that is re-reflected and re-incident on the fourth optical layer 217c. In addition, the re-incident light may be incident on the polarizing layer 293. In this case, since the light L3a incident on the polarizing layer 293 is incident at an angle smaller than the total reflection angle, the light internally totally reflected in the polarizing layer 293 can be reduced. Accordingly, the amount of light emitted to the outside from the polarizing layer 293 may increase, thereby increasing light extraction efficiency. Accordingly, by further increasing the light extraction efficiency of the display apparatus, the display apparatus can be driven at low power.

A display apparatus according to example embodiments of the present disclosure may be described as follows.

A display apparatus according to an embodiment of the present disclosure may include a substrate, a plurality of pixel driving circuits disposed on the substrate, a plurality of light-emitting elements disposed on the pixel driving circuits and electrically connected to the pixel driving circuits, respectively, at least one optical layer covering the plurality of light-emitting elements, and a cover layer disposed on the optical layer, in which a refractive index of the cover layer is smaller than or equal to a refractive index of one of the at least one optical layer.

According to example embodiments of the present disclosure, the at least one optical layer may include a first optical layer covering side surfaces of the plurality of light-emitting elements, a second optical layer disposed outside the first optical layer, and a third optical layer disposed on the first optical layer.

According to example embodiments of the present disclosure, the at least one optical layer may include a first optical layer covering side surfaces of the plurality of light-emitting elements, a second optical layer disposed outside the first optical layer, and a fourth optical layer disposed on the first optical layer, and the fourth optical layer may have a smooth surface to increase a total internal reflection of incident light incident on an interface with the cover layer.

According to example embodiments of the present disclosure, the fourth optical layer may include the same material as the first optical layer.

According to example embodiments of the present disclosure, the cover layer may cover at least areas in which the plurality of light-emitting elements are disposed.

According to example embodiments of the present disclosure, the cover layer may include a transparent organic insulation material.

According to example embodiments of the present disclosure, the fourth optical layer may include a first insulation material having particles dispersed therein, and the cover layer may include a second insulation material having scattering particles dispersed therein.

According to example embodiments of the present disclosure, the scattering particles may include hollow silica, and the particles may include metal particles.

According to example embodiments of the present disclosure, the second insulation material may include an organic siloxane resin.

According to example embodiments of the present disclosure, a refractive index of the fourth optical layer may range from 1.50 to 1.55, and a refractive index of the cover layer may range from 1.37 to 1.39.

According to example embodiments of the present disclosure, the refractive index of the fourth optical layer may be more than 1.53, the refractive index of the cover layer may be less than 1.38, and a difference in the refractive indexes of the fourth optical layer and the cover layer may be more than at least 0.15.

According to example embodiments of the present disclosure, the plurality of light-emitting elements may be micro light-emitting elements.

According to example embodiments of the present disclosure, the plurality of light-emitting elements may include a pair of light-emitting elements that emit light of the same color, one of the pair of light-emitting elements may be a main light-emitting element, and the other one of the pair of light-emitting elements may be a redundancy light-emitting element.

According to example embodiments of the present disclosure, the fourth optical layer may come into contact with the cover layer.

According to example embodiments of the present disclosure, light emitted from the plurality of light-emitting elements may include light that is totally reflected at an interface between the fourth optical layer and the cover layer, and the totally reflected light may be re-incident light that is re-reflected and re-incident on the fourth optical layer.

According to example embodiments of the present disclosure, the plurality of light-emitting elements may include micro light-emitting elements having a vertical structure.

According to example embodiments of the present disclosure, the display apparatus may further include a bank on which the plurality of light-emitting elements are disposed, a first electrode disposed between the bank and one side of each light-emitting element and electrically connected to a respective pixel driving circuit of the plurality of pixel driving circuits, and a second electrode disposed at the other side of each light-emitting element.

According to example embodiments of the present disclosure, each light-emitting element may be electrically connected to the first electrode by eutectic bonding.

According to example embodiments of the present disclosure, a refractive index of the third optical layer ranges from 1.50 to 1.55, and the refractive index of the cover layer ranges from 1.50 to 1.55.

According to example embodiments of the present disclosure, the third optical layer has an uneven upper surface

According to the embodiments of the present disclosure, it is possible to increase the ratio of light totally reflected at the interface between the optical layer and the cover layer that are disposed below the polarizing layer.

Accordingly, since the incident angle of the light incident on the polarizing layer is smaller than the total reflection angle, it is possible to increase light extraction efficiency. It is possible to increase light extraction efficiency, thereby reducing power consumption.

In addition, according to the embodiments of the present disclosure, by arranging the optical layer having the relatively smooth surface by reducing the surface roughness of the optical layer, it is possible to increase the amount of light totally reflected at the interface between the optical layer and the cover layer.

Accordingly, according to the embodiments of the present disclosure, it is possible to increase light extraction efficiency in the display area.

Effects of the present disclosure are not limited to the above-described effects, and other effects that are not described will be able to be clearly understood by those skilled in the art based on the above description.

Although the embodiments of the present disclosure have been described in more detail with reference to the accompanying drawings, the present disclosure is not necessarily limited to these embodiments, and various modifications may be carried out without departing from the technical spirit of the present disclosure. Accordingly, the embodiments disclosed in the present disclosure are not intended to limit the technical spirit of the present disclosure, but is intended to describe the same, and the scope of the technical spirit of the present disclosure is not limited by these embodiments. Accordingly, it should be understood that the above-described embodiments are illustrative and not restrictive in all aspects.

What is claimed is:

1. A display apparatus comprising:
a substrate;
a plurality of pixel driving circuits on the substrate;
a plurality of light-emitting elements on the plurality of pixel driving circuits and electrically connected to the plurality of pixel driving circuits, respectively;
at least one optical layer covering the plurality of light-emitting elements; and
a cover layer on the at least one optical layer,
wherein a refractive index of the cover layer is less than or equal to a refractive index of one of the at least one optical layer.

2. The display apparatus of claim 1, wherein the at least one optical layer includes:
a first optical layer covering side surfaces of the plurality of light-emitting elements;
a second optical layer outside the first optical layer; and
a third optical layer on the first optical layer.

3. The display apparatus of claim 1, wherein the at least one optical layer includes:
a first optical layer covering side surfaces of the plurality of light-emitting elements;
a second optical layer outside the first optical layer; and
a fourth optical layer on the first optical layer, the fourth optical layer having a smooth surface and increasing a total internal reflection of incident light incident on an interface with the cover layer.

4. The display apparatus of claim 3, wherein the fourth optical layer includes a same material as the first optical layer.

5. The display apparatus of claim 1, wherein the cover layer covers at least areas in which the plurality of light-emitting elements are disposed.

6. The display apparatus of claim 5, wherein the cover layer includes an organic insulation material.

7. The display apparatus of claim 3, wherein the fourth optical layer includes a first insulation material having particles dispersed therein and the cover layer includes a second insulation material having scattering particles dispersed therein.

8. The display apparatus of claim 7, wherein the scattering particles include hollow silica and the particles include metal particles.

9. The display apparatus of claim 7, wherein the second insulation material includes an organic siloxane resin.

10. The display apparatus of claim 3, wherein a refractive index of the fourth optical layer ranges from 1.50 to 1.55 and a refractive index of the cover layer ranges from 1.37 to 1.39.

11. The display apparatus of claim 10, wherein the refractive index of the fourth optical layer is greater than 1.53, the refractive index of the cover layer is less than 1.38, and a difference in the refractive index of the fourth optical layer and the refractive index of the cover layer is greater than at least 0.15.

12. The display apparatus of claim 1, wherein the plurality of light-emitting elements are micro light-emitting elements.

13. The display apparatus of claim 1, wherein the plurality of light-emitting elements include a pair of light-emitting elements that emit light of a same color, and
one of the pair of light-emitting elements is a main light-emitting element and another one of the pair of light-emitting elements is a redundancy light-emitting element.

14. The display apparatus of claim 3, wherein the fourth optical layer contacts the cover layer.

15. The display apparatus of claim 3, wherein light emitted from the plurality of light-emitting elements includes light totally reflected at an interface between the fourth optical layer and the cover layer, and the totally reflected light is re-incident light that is re-reflected and re-incident on the fourth optical layer.

16. The display apparatus of claim 1, wherein the plurality of light-emitting elements are micro light-emitting elements having a vertical structure.

17. The display apparatus of claim 1, further comprising:
a bank on which the plurality of light-emitting elements are disposed;
a first electrode between the bank and one side of each light-emitting element, the first electrode electrically connected to a respective pixel driving circuit of the plurality of pixel driving circuit; and
a second electrode at another side of each light emitting element.

18. The display apparatus of claim 17, wherein each light-emitting element is electrically connected to the first electrode by eutectic bonding.

19. The display apparatus of claim 2, wherein a refractive index of the third optical layer ranges from 1.50 to 1.55 and the refractive index of the cover layer ranges from 1.50 to 1.55.

20. The display apparatus of claim 2, wherein the third optical layer has an uneven upper surface.
